(19) United States
(12) Patent Application Publication
(10) Pub. No.: US 2025/0221255 A1
(43) Pub. Date: Jul. 3, 2025

(54) DISPLAY DEVICE

(71) Applicant: LG Display Co., Ltd., Seoul (KR)

(72) Inventors: Miso KIM, Paju-si (KR); Daehee KIM, Paju-si (KR)

(73) Assignee: LG Display Co., Ltd., Seoul (KR)

(21) Appl. No.: 18/783,182

(22) Filed: Jul. 24, 2024

(30) Foreign Application Priority Data
Dec. 29, 2023 (KR) 10-2023-0196466

(51) Int. Cl. H10K 59/80; G09G 3/3233; H10K 59/122

(52) U.S. Cl. CPC H10K 59/873; H10K 59/122; G09G 3/3233; G09G 2300/0842

(57) ABSTRACT

A display device in one example includes a planarization layer disposed on a substrate, an emission layer disposed on the planarization layer in the display area, an outermost bank disposed on the planarization layer in the dam area, a first overhang structure disposed to overlap with the outermost bank, and a second overhang structure disposed to overlap with the first overhang structure. The display device can prevent the penetration of external moisture or oxygen.

### CROSS-REFERENCE TO RELATED APPLICATION

This application claims priority to Korean Patent Application No. 10-2023-0196466, filed on Dec. 29, 2023 in the Korean Intellectual Property Office, the entire contents of which is hereby expressly incorporated by reference into the present application.

### BACKGROUND

### Field

The present disclosure relates to electronic devices with display, and more specifically, to display devices with improved properties.

### Discussion of the Related Art

As the information-oriented society has been developed, various needs for display devices for displaying images have increased. Recently, various types of display devices, such as liquid crystal display (LCD) devices, organic light emitting diode (OLED) display devices, and the like have been developed and widely used.

Display devices can include a display panel, one or more driving circuit, a controller, and the like. The display panel includes pixels configured to display images.

### SUMMARY OF THE DISCLOSURE

Elements (e.g., light emitting elements ED including an organic material) included in a display panel can be vulnerable to external moisture or oxygen, and the like. If moisture or oxygen penetrates into the display panel, the display panel may not operate properly and can be damaged. Accordingly, there is a need for a display device capable of preventing external moisture or oxygen from penetrating into a display panel.

To address this issue, one or more embodiments of the present disclosure can provide a display device capable of preventing the penetration of external moisture or oxygen.

One or more embodiments of the present disclosure can provide a display device configured to have an extremely narrow bezel.

One or more embodiments of the present disclosure can provide a display device capable of preventing the penetration of external moisture or oxygen and thereby implementing low power consumption.

According to aspects of the present disclosure, a display device includes a substrate including a display area and a dam area, a planarization layer disposed over the substrate, an emission layer disposed on the planarization layer in the display area, an outermost bank on the planarization layer in the dam area, a first overhang structure disposed to overlap with the outermost bank, and a second overhang structure disposed to overlap with the first overhang structure.

According to one or more embodiments of the present disclosure, a display device is capable of preventing the penetration of external moisture or oxygen.

According to one or more embodiments of the present disclosure, a display device is configured to have an extremely narrow bezel.

According to one or more embodiments of the present disclosure, a display device is capable of preventing the penetration of external moisture or oxygen and thereby implementing low power consumption.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIG. 1 illustrates an example system configuration of a display device according to aspects of the present disclosure;

FIG. 2 illustrates an example display panel according to aspects of the present disclosure;

FIG. 3 illustrates an example substrate of the display panel according to aspects of the present disclosure;

FIG. 4 is an example cross-sectional view of a display area of the display panel according to aspects of the present disclosure;

FIG. 5 illustrates an example overhang structure in the display panel according to aspects of the present disclosure;

FIGS. 6, 7, and 8 illustrate different examples of an overhang structure in the display panel according to aspects of the present disclosure;

FIG. 9 illustrates areas where the overhang structures are configured in the display panel according to aspects of the present disclosure;

FIG. 10 illustrates an example cross-sectional view of the display panel with the overhang structure according to aspects of the present disclosure;

FIGS. 11 and 12 are example cross-sectional views of the display panel according to aspects of the present disclosure;

FIGS. 13, 14, and 15 illustrate an example manufacturing process of the display panel according to aspects of the present disclosure; and

FIG. 16 illustrates an example process of forming an overhang structure in the display panel according to aspects of the present disclosure.

### DETAILED DESCRIPTION OF THE EMBODIMENTS

Reference will now be made in detail to embodiments of the present disclosure, examples of which can be illustrated in the accompanying drawings. In the following description, the structures, embodiments, implementations, methods and operations described herein are not limited to the specific example or examples set forth herein and can be changed as is known in the art, unless otherwise specified. Like reference numerals designate like elements throughout, unless otherwise specified. Names of the respective elements used in the following explanations are selected only for convenience of writing the disclosure and can thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure.

Further, the protected scope of the present disclosure is defined by claims and their equivalents. In the following description, where the detailed description of the relevant known function or configuration can unnecessarily obscure aspects of the present disclosure, a detailed description of such known function or configuration can be omitted.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. Where the terms “comprise,” “have,” “include,” “contain,” “constitute,” “make up of,” “formed of,” and the like are used, one or more other elements can be added unless the term, such as “only,” is used. An element described in the singular form is intended to include a plurality of elements, and vice versa, unless the context clearly indicates otherwise.

Although the terms “first,” “second,” A, B, (a), (b), and the like can be used herein to describe various elements, these elements should not be interpreted to be limited by these terms as they are not used to define a particular order or precedence. These terms are used only to distinguish one element from another and may not define order or sequence. For example, a first element could be termed a second element, and, similarly, a second element could be termed a first element, without departing from the scope of the present disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

Where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third element or layer can be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings and coverages of the term “may”.

Hereinafter, various embodiments of the present disclosure will be described in detail with reference to the attached drawings. All the components of each display device or apparatus according to all embodiments of the present disclosure are operatively coupled and configured.

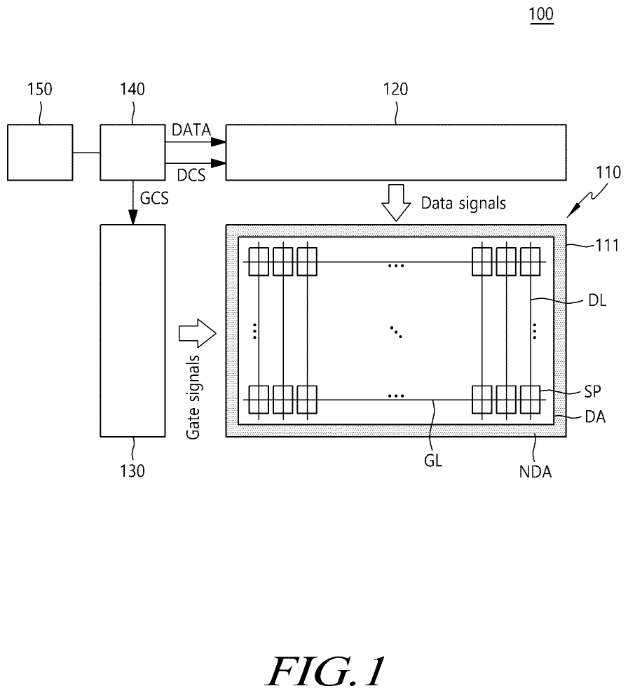

FIG. 1 illustrates an example system configuration of a display device 100 according to aspects of the present disclosure.

Referring to FIG. 1, in one or more embodiments, the display device 100 can include a display panel 110 and a display driving circuit as components for displaying an image. The display driving circuit can be a circuit for driving the display panel 110, and include a data driving circuit 120, a gate driving circuit 130, a display controller 140, and other circuit components.

The display panel 110 can include a substrate 111 and a plurality of subpixels SP disposed on the substrate 111.

The substrate 111 of the display panel 110 can include a display area DA allowing an image to be displayed and a non-display area NDA located outside of the display area DA. The non-display area NDA can surround the display area DA entirely or only in part.

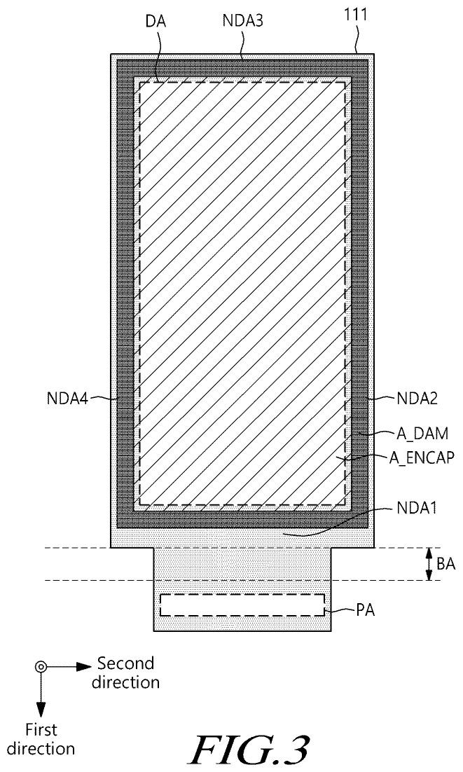

The plurality of subpixels SP for displaying an image can be disposed in the display area DA, and the non-display area NDA can include a pad area PA (for example, as shown in FIG. 3) located in a first direction from the display area DA.

In the display panel 110 according to embodiments of the present disclosure, the non-display area NDA can have a very small area compared with the display area DA. Herein, the non-display area NDA can also be referred to as a “bezel.”

For example, the non-display area NDA can include a first non-display area located outside of the display area DA in a first direction, a second non-display area located outside of the display area DA in a second direction intersecting the first direction, a third non-display area located outside of the display area DA in a direction opposite to the first direction, and a fourth non-display area located outside of the display area DA in a direction opposite to the second direction. One or two non-display areas among the first to fourth non-display areas can include a pad area to which the data driving circuit 120 is connected or bonded. For example, among the first to fourth non-display areas, each of the remaining two or three non-display areas, which do not include the pad area, can have a very small size compared with the one or two non-display areas.

In an embodiment, a boundary area between the display area DA and the non-display area NDA can be bent, and thereby, the non-display area NDA can be located under the display area DA. In this embodiment, when a user views the display device 100 in front thereof, all or most of the non-display area NDA may not be visible to the user.

Various types of signal lines for driving a plurality of subpixels SP can be disposed on the substrate 111 of the display panel 110.

In one or more embodiments, the display device 100 according to aspects of the present disclosure can be a liquid crystal display device, or the like, or a self-emission display device in which light is emitted from the display panel 110 itself. In an example where the display device 100 according to aspects of the present disclosure is the self-emission display device, each of the plurality of subpixels SP can include a light emitting element.

For example, the display device 100 according to aspects of the present disclosure can be an organic light emitting display device implemented with organic light emitting diodes (OLED) as light emitting elements. In another example, the display device 100 according to aspects of the present disclosure can be an inorganic light emitting display device implemented with inorganic material-based light emitting diodes as light emitting elements. In further another example, the display device 100 according to aspects of the present disclosure can be a quantum dot display device implemented with quantum dots, which are self-emission semiconductor crystals, as light emitting elements.

The structure of each of the plurality of subpixels SP can depend on types of display device 100. For example, in an example where the display device 100 is a self-emission display device including self-emission subpixels SP, each subpixel SP can include a self-emission light emitting element, one or more transistors, and one or more capacitors.

The various types of signal lines can include, for example, a plurality of data lines DL for carrying data signals (which can be referred to as data voltages or image signals), a plurality of gate lines GL for carrying gate signals (which can be referred to as scan signals), and the like.

In one or more embodiments, the plurality of data lines DL and the plurality of gate lines GL can intersect one another. Each of the plurality of data lines DL can be disposed while extending in a first direction, and each of the plurality of gate lines GL can be disposed while extending in a second direction. For example, the first direction can be a column or vertical direction, and the second direction can be a row or horizontal direction. In another example, the first direction can be the row or horizontal direction, and the second direction can be the column or vertical direction. Hereinafter, for convenience of explanation, discussions can be provided based on examples where each of a plurality of data lines DL is disposed in the column direction, and each of a plurality of gate lines GL is disposed in the row direction, but embodiments of the present disclosure are not limited thereto.

The data driving circuit 120 can be a circuit for driving a plurality of data lines DL and can output data signals to the plurality of data lines DL.

The data driving circuit 120 can receive image data DATA in digital form from the display controller 140, convert the received image data DATA into data signals in analog form, and output converted data signals to the plurality of data lines DL.

In one or more embodiments, the data driving circuit 120 can be connected to the display panel 110 using a tape-automated-bonding (TAB) technique, or connected to a conductive pad such as a bonding pad of the display panel 110 using a chip-on-glass (COG) technique or a chip-on-panel (COP) technique, or connected to the display panel 110 using a chip-on-film (COF) technique.

The data driving circuit 120 can be located in, and/or electrically connected to, but not limited to, only one side or portion (e.g., an upper edge or a lower edge) of the display panel 110. In one or more embodiments, the data driving circuit 120 can be disposed in, and/or electrically connected to, but not limited to, two sides or portions (e.g., an upper edge and a lower edge) of the display panel 110 or at least two of four sides or portions (e.g., the upper edge, the lower edge, a left edge, and a right edge) of the display panel 110 according to driving schemes, panel design schemes, or other design requirements.

The data driving circuit 120 can be connected to outside, or an edge, of the display area DA of the display panel 110, or be disposed in the display area DA of the display panel 110.

The gate driving circuit 130 can be a circuit for driving a plurality of gate lines GL and can output gate signals to the plurality of gate lines GL.

The gate driving circuit 130 can receive various types of gate driving control signals GCS, and further, receive a first gate voltage corresponding to a turn-on level voltage and a second gate voltage corresponding to a turn-off level voltage. Thereby, the gate driving circuit 130 can generate gate signals and supply the generated gate signals to the plurality of gate lines GL.

In one or more embodiments, the gate driving circuit 130 included in the display device 100 can be embedded into the display panel 110 using a gate-in-panel (GIP) technique. In an example where the gate driving circuit 130 is implemented using the gate-in-panel (GIP) technique, the gate driving circuit 130 can be disposed on the substrate 111 of the display panel 110 during the manufacturing process of the display panel 110 or display device 100.

In one embodiment, the gate driving circuit 130 included in the display device 100 can be disposed in the display area DA of the display panel 110. In this implementation, for example, the gate driving circuit 130 can be disposed in, and/or electrically connected to, but not limited to, a first area (e.g., a left area or a right area of the display area DA) of the display area DA of the display panel 110. In another example, the gate driving circuit 130 can be disposed in, and/or electrically connected to, but not limited to, a first area (e.g., a left area or a right area of the display area DA) and a second area (e.g., the right area or the left area of the display area DA) of the display area DA of the display panel 110.

Herein, the gate driving circuit 130 embedded in the display panel 110 using the gate-in-panel (GIP) technique can also be referred to as a “gate-in-panel circuit.”

The display controller 140 can be a device for controlling the data driving circuit 120 and the gate driving circuit 130, and can control driving timing for the plurality of data lines DL and driving timing for the plurality of gate lines GL.

The display controller 140 can supply a data driving control signal DCS to the data driving circuit 120 to control the data driving circuit 120, and supply a gate driving control signal GCS to the gate driving circuit 130 to control the gate driving circuit 130.

The display controller 140 can receive image data input from a host system 150 and supply image data DATA readable by the data driving circuit 120 based on the input image data to the data driving circuit 120.

The display controller 140 can be implemented in a separate component from the data driving circuit 120, or incorporated in the data driving circuit 120 and thus implemented in an integrated circuit.

The display controller 140 can be a timing controller used in the typical display technology or a controller or a control device capable of performing other control functions in addition to the function of the typical timing controller. In one or more embodiments, the display controller 140 can be a controller or a control device different from the timing controller, or a circuitry or a component included in the controller or the control device. The display controller 140 can be implemented using various circuits or electronic components such as an integrated circuit (IC), a field programmable gate array (FPGA), an application specific integrated circuit (ASIC), a processor, and/or the like.

The display controller 140 can be mounted on a printed circuit board, a flexible printed circuit, and/or the like and be electrically connected to the gate driving circuit 130 and the data driving circuit 120 through the printed circuit board, flexible printed circuit, and/or the like.

The display controller 140 can transmit signals to, and receive signals from, the data driving circuit 120 via one or more predefined interfaces. For example, such interfaces can include a low voltage differential signaling (LVDS) interface, an embedded clock point-point interface (EPI), a serial peripheral interface (SPI), and the like. However, embodiments of the present disclosure are not limited thereto.

In one or more aspects, to provide a touch sensing function, as well as an image display function, the display device 100 can include a touch sensor, and a touch sensing circuit configured to sense the touch sensor and detect the presence or absence of a touch by an object such as a finger, a pen, or the like, or the location of the touch.

The touch sensing circuit can include a touch driving circuit configured to drive and sense the touch sensor and generate and output touch sensing data, and a touch controller capable of detecting the presence or absence of a touch or the location of the touch using the touch sensing data.

The touch sensor can include a plurality of touch electrodes. The touch sensor can further include a plurality of touch lines to electrically connect the plurality of touch electrodes to the touch driving circuit.

The touch sensor can be implemented in the form of a touch panel outside of the display panel 110 or be integrated into the display panel 110. In the example where the touch sensor is implemented in the form of the touch panel outside of the display panel 110, such a touch sensor can be referred to as an add-on type. In the example where the add-on type of touch sensor is disposed in the display device 100, the touch panel and the display panel 110 can be separately manufactured and combined in an assembly process. The add-on type of touch panel can include a touch panel substrate and a plurality of touch electrodes disposed on the touch panel substrate.

In the example where the touch sensor is disposed inside of the display panel 110, the touch sensor can be formed on the substrate along with signal lines and electrodes related to display driving during the manufacturing process of the display panel 110.

The touch driving circuit can supply a touch driving signal to at least one of a plurality of touch electrodes and generate touch sensing data by sensing at least one of the plurality of touch electrodes.

The touch sensing circuit can perform touch sensing using a self-capacitance sensing technique or a mutual-capacitance sensing technique.

In the example where the touch sensing circuit performs touch sensing using the self-capacitance sensing technique, the touch sensing circuit can perform touch sensing based on capacitance between each touch electrode and a touch object (e.g., a finger, a pen, and the like). According to the self-capacitance sensing technique, each of a plurality of touch electrodes can serve as both a driving touch electrode and a sensing touch electrode. The touch driving circuit can drive all, or one or more, of a plurality of touch electrodes and sense all, or one or more, of the plurality of touch electrodes.

In the example where the touch sensing circuit performs touch sensing using the mutual-capacitance sensing technique, the touch sensing circuit can perform touch sensing based on a capacitance between touch electrodes. According to the mutual-capacitance sensing technique, a plurality of touch electrodes can be divided into driving touch electrodes and sensing touch electrodes. The touch driving circuit can drive the driving touch electrodes and sense the sensing touch electrodes.

In one or more aspects, the touch driving circuit and touch controller included in the touch sensing circuit can be implemented in separate devices or in a single device. In one or more aspects, the touch driving circuit and the data driving circuit can be implemented in separate devices or in a single device.

The display device 100 can further include a power supply circuit for supplying various types of power to the display driving circuit and/or the touch sensing circuit.

In one or more embodiments, the display device 100 according to aspects of the present disclosure can represent, but not limited to, a mobile terminal, such as a smart phone, a tablet, or the like, a monitor, a television (TV), or the like. Embodiments of the present disclosure are not limited thereto. In one or more embodiments, the display device 100 can be display devices, or include displays, of various types, sizes, and shapes for displaying information or images.

In one or more embodiments, the display device 100 can further include an electronic device such as a camera (e.g., an image sensor), a sensor capable of detecting an object, and the like. For example, the sensor can be a sensor capable of detecting an object or a human body by receiving light such as infrared light, ultrasonic light, ultraviolet light or the like.

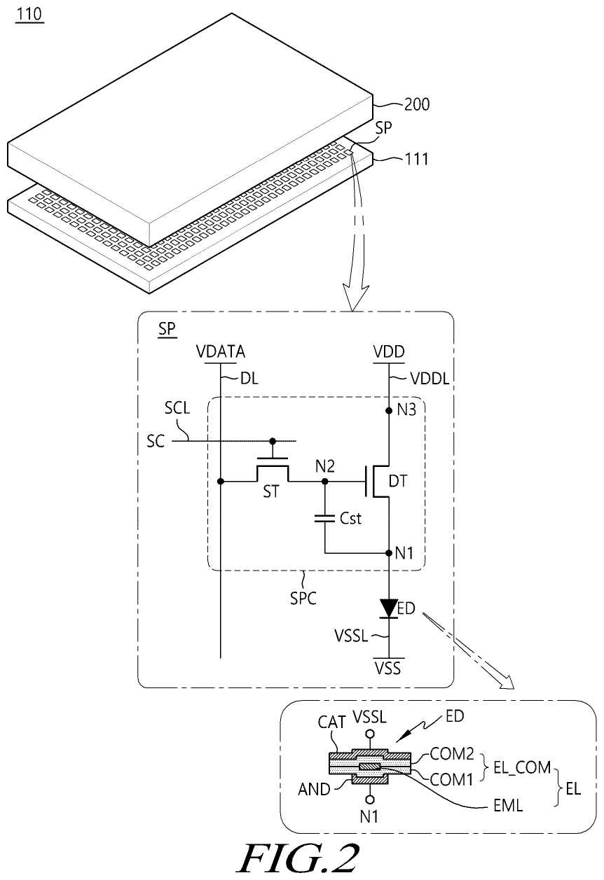

FIG. 2 illustrates an example configuration of the display panel 110 according to aspects of the present disclosure.

Referring to FIG. 2, the display panel 110 can include a substrate 111 on which a plurality of subpixels SP are disposed, and an encapsulation layer 200 over the substrate 111. The encapsulation layer 200 can also be referred to as an encapsulation substrate or a sealing element.

In an example where the display device 100 is a self-emission display device, each of the plurality of subpixels SP disposed on the substrate 111 can include a light emitting element ED and a subpixel circuit SPC for driving the light emitting element ED.

The subpixel circuit SPC can include a plurality of pixel driving transistors and at least one capacitor for driving the light emitting element ED. The subpixel circuit SPC can drive the light emitting element ED by supplying a driving current to the light emitting element ED at a predetermined timing. The light emitting element ED can be driven by the driving current to emit light.

The plurality of pixel driving transistors can include a driving transistor DT for driving the light emitting element ED and a scan transistor ST configured to turn on or off according to a scan signal SC.

The driving transistor DT can supply a driving current to the light emitting element ED. The scan transistor ST can be configured to control an electrical state of a corresponding node in the subpixel circuit SPC or to control the state or operation of the driving transistor DT.

At least one capacitor can include a storage capacitor Cst configured to maintain a constant voltage during a display frame or a certain period of the display frame.

To drive one or more subpixels SP, a data signal VDATA, which is an image signal, and a scan signal SC, which is a gate signal, can be applied to the subpixel SP. Further, a common pixel driving voltage including a first common driving voltage VDD and a second common driving voltage VSS can be applied to the one or more subpixels SP.

The light emitting element ED can include an anode AND, a light emitting element intermediate layer EL, and a cathode CAT. The light emitting element intermediate layer EL can be disposed between the anode AND and the cathode CAT. The light emitting element intermediate layer EL can also be referred to as “an emission layer”.

In an example where the light emitting element ED is an organic light emitting diode, the light emitting element intermediate layer EL can include an emitting material layer EML, a first common intermediate layer COM1 between the anode AND and the emitting material layer EML, and a second common intermediate layer COM2 between the emitting material layer EML and the cathode CAT. The emitting material layer EML can be disposed in each subpixel SP. The first common intermediate layer COM1 and the second common intermediate layer COM2 can be commonly disposed across a plurality of subpixels SP. The emitting material layer EML can be disposed in each subpixel SP, and the first common intermediate layer COM1 and the second common intermediate layer COM2 can be commonly disposed across the light emitting areas and non-light emitting areas of a plurality of subpixels SP. A layer including the first common intermediate layer COM1 and the second common intermediate layer COM2 can be referred to as a common intermediate layer EL_COM.

For example, the first common intermediate layer COM1 can include a hole injection layer (HIL), a hole transfer layer (HTL), and the like. The second common intermediate layer COM2 can include an electron transport layer (ETL), an electron injection layer (EIL), and the like. The hole injection layer can inject holes from the anode AND to the hole transport layer, the hole transport layer can transport holes to the emitting material layer EML, the electron injection layer can inject electrons from the cathode ACT to the electron transport layer, and the electron transport layer can transport electrons to the emitting material layer EML.

For example, the cathode CAT can be electrically connected to a second common driving voltage line VSSL. A second common driving voltage VSS, which is a type of common pixel driving voltage, can be applied to the cathode CAT through the second common driving voltage line VSSL. The anode AND can be electrically connected to a first node N1 of a corresponding driving transistor DT of each subpixel SP. Herein, the second common driving voltage VSS can also be referred to as a “base voltage”, and the second common driving voltage line VSSL can also be referred to as a “base voltage line”.

For example, the anode AND can be a pixel electrode disposed in each subpixel SP, and the cathode CAT can be a common electrode commonly disposed in a plurality of subpixels SP. In another example, the cathode CAT can be a pixel electrode disposed in each subpixel SP, and the anode AND can be a common electrode commonly disposed in a plurality of subpixels SP. Herein, for convenience of explanation, discussions can be provided based on examples where the anode AND is a pixel electrode, and the cathode CAT is a common electrode.

Each light emitting element ED can be configured by respective portions of the anode AND, the light emitting element intermediate layer EL, and the cathode CAT, which overlap with each other. A corresponding light emitting area can be formed in each light emitting element ED. For example, a corresponding light emitting area of each light emitting element ED can include an area in which the anode AND, the light emitting element intermediate layer EL, and the cathode CAT overlap with each other.

In some embodiments, the light emitting element ED can be an organic light emitting diode (OLED), an inorganic material-based light emitting diode (LED), or a quantum dot light emitting element. For example, in an example where the light emitting element ED is an organic light emitting diode OLED, the light emitting element intermediate layer EL of this light emitting element ED can be a light emitting element intermediate layer including an organic material.

The driving transistor DT can be a transistor configured to supply a driving current to the light emitting element ED. The driving transistor DT can be connected between a first common driving voltage line VDDL and the light emitting element ED.

The driving transistor DT can include a first node N1 electrically connected with the light emitting element ED, a second node N2 to which a data signal VDATA is applied, and a third node N3 to which a driving voltage VDD through a driving voltage line DVL (e.g., the first common driving voltage line VDDL) is applied.

In the driving transistor DT, the second node N2 can be a gate node, the first node N1 can be a source node or a drain node, and the third node N3 can be the drain node or the source node. Hereinafter, for merely convenience of explanation, discussions can be provided based on examples where the first, second, and third nodes (N1, N2, and N3) of the driving transistor DT are source, gate, and drain nodes, respectively. However, embodiments of the present disclosure are not limited thereto.

The scan transistor ST included in the subpixel circuit SPC illustrated in FIG. 2 can be a switching transistor for allowing a data signal VDATA, which is an image signal, to be supplied to the second node N2, which is the gate node of the driving transistor DT.

The scan transistor ST can turn on or turn off by a scan signal SC, which is a type of gate signal, applied through a scan line SCL, which is a type of gate line GL, and control an electrical connection between the second node N2 of the driving transistor DT and a data line DL. The drain electrode or source electrode of the scan transistor ST can be electrically connected to the data line DL. The source electrode or drain electrode of the scan transistor ST can be electrically connected to the second node N2 of the driving transistor DT. The gate electrode of the scan transistor ST can be electrically connected to the scan line SCL.

The storage capacitor Cst can be electrically connected between the first node N1 and the second node N2 of the driving transistor DT. The storage capacitor Cst can include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

In one or more embodiments, the storage capacitor Cst, which can be present between the first node N1 and the second node N2 of the driving transistor DT, can be an external capacitor intentionally configured or designed to be located outside of the driving transistor DT, other than internal capacitors, such as parasitic capacitors (e.g., a gate-to-source capacitance Cgs, a gate-to-drain capacitance Cgd, and the like).

Each of the driving transistor DT and the scan transistor ST can be an n-type transistor or a p-type transistor.

The display panel 110 can have a top emission structure or a bottom emission structure.

In an example where the display panel 110 has the top emission structure, at least a portion of the subpixel circuit SPC can overlap with at least a portion of the light emitting element ED in the vertical direction. In an example where the display panel 110 has the bottom emission structure, the subpixel circuit SPC may not overlap the light emitting element ED in the vertical direction.

The subpixel circuit SPC can include two transistors (2T: DT and ST) and one capacitor (1C: Cst) (which can be referred to as a “2T1C structure”), and in some implementations, can further include one or more transistors, or further include one or more capacitors.

For example, the subpixel circuit SPC can have an 8T1C structure including 8 transistors and 1 capacitor. In another example, the subpixel circuit SPC can have an 6T2C structure including 6 transistors and 2 capacitor. In further another example, the subpixel circuit SPC can have an 7T1C structure including 7 transistors and 1 capacitor.

The types and number of gate signals supplied to a subpixel SP, and/or the types and number of gate lines connected to the subpixel SP can vary depending on a structure of a corresponding subpixel circuit SPC.

Further, the types and number of common pixel driving voltages supplied to a subpixel SP can vary depending on a structure of a corresponding subpixel circuit SPC.

Since circuit elements (e.g., a light emitting element ED such as an organic light emitting diode (OLED) including an organic material) in each subpixel SP are vulnerable to external moisture or oxygen, an encapsulation layer 200 can be disposed in the display panel 110 in order to prevent the external moisture or oxygen from penetrating into the circuit elements (e.g., the light emitting element ED). The encapsulation layer 200 can be disposed in various shapes or configurations to prevent light emitting elements ED from contacting moisture or oxygen.

FIG. 3 illustrates an example structure of the substrate 111 of the display panel 110 according to aspects of the present disclosure.

Referring to FIG. 3, in one or more embodiments, the substrate 111 of the display panel 110 can include a display area DA allowing an image to be displayed and a non-display area NDA in which an image is not displayed.

The non-display area NDA can include, for example, a first non-display area NDA1 located outside of the display area DA in a first direction, a second non-display area NDA2 located outside of the display area DA in a second direction, a third non-display area NDA3 located outside of the display area DA in a direction opposite to the first direction, and a fourth non-display area NDA4 located outside of the display area DA in a direction opposite to the second direction. For example, the first direction can be a column direction (e.g., a Y-axis direction), and the second direction intersecting the first direction can be a row direction (e.g., an X-axis direction).

The first non-display area NDA1 can include a pad area PA in which a plurality of pads are disposed.

One or more driving circuits can be electrically connected to one or more pads disposed in the pad area PA. A plurality of driving circuits or one or more printed circuit boards can be electrically connected to pads disposed in the pad area PA. For example, the plurality of pads can include a plurality of display pads and a plurality of touch pads. A plurality of data lines DL, a first common driving voltage line VDDL, a second common driving voltage line VSSL, and the like can be electrically connected to the plurality of display pads. A plurality of touch routing lines TL can be electrically connected to the plurality of touch pads.

In one or more embodiments, the first non-display area NDA1 can further include a bending area BA. In these embodiments, the substrate 111 can be a flexible substrate. In one or more embodiments, the first non-display area NDA1 may not include a bending area BA.

The display panel 110 can further include a ground line disposed in the non-display area NDA of the substrate 111. The ground line can be disposed such that the ground line runs from one point of the pad area PA to another point of the pad area PA via the second non-display area NDA2, the third non-display area NDA3, and the fourth non-display area NDA4.

The display panel 110 can include an encapsulation layer area A_ENCAP and a dam area A_DAM.

The encapsulation layer area A_ENCAP can be an area in which an encapsulation layer 200 is disposed. In one or more embodiments, the encapsulation layer 200 included in the display panel 110 can have a structure in which at least one inorganic layer and at least one organic layer are stacked. In these embodiments, an edge of the encapsulation layer 200 can be an edge of an organic layer included in the encapsulation layer 200.

The dam area A_DAM can be an area surrounding the encapsulation layer area A_ENCAP. A structure functioning as a dam can be located in the dam area A_DAM. The dam can prevent an organic layer of a liquid state from flowing outwardly.

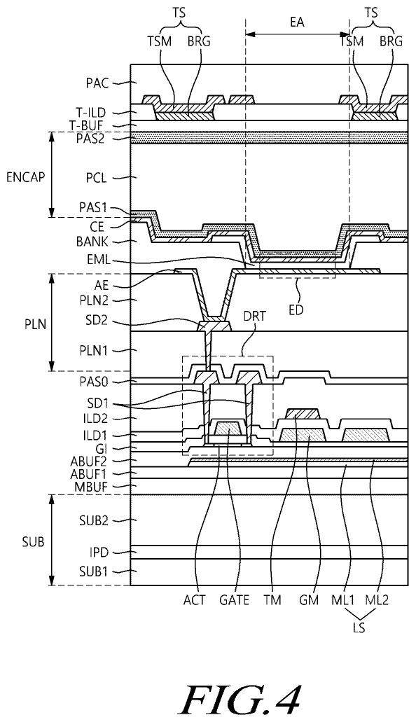

FIG. 4 is an example cross-sectional view of a display area DA of the display panel 110 according to aspects of the present disclosure.

Referring to FIG. 4, the substrate SUB of the display panel 110 can include a first substrate SUB1, an interlayer insulating layer IPD, and a second substrate SUB2. The interlayer insulating layer IPD can be interposed between the first substrate SUB1 and the second substrate SUB2. As the substrate SUB includes the first substrate SUB1, the interlayer insulating layer IPD, and the second substrate SUB2, the substrate SUB can prevent or reduce the penetration of moisture. The first substrate SUB1 and the second substrate SUB2 can be, for example, polyimide (PI) substrates. The first substrate SUB1 can be referred to as a primary PI substrate, and the second substrate SUB2 can be referred to as a secondary PI substrate.

Various types of patterns (ACT1, SD1, GATE1) for forming transistors such as a driving transistor DRT, various insulating layers (MBUF, ABUF1, ABUF2, GI, ILD1, ILD2, PAS0), and various types of metal patterns (TM1, GM, ML1, ML2) can be disposed on the substrate SUB.

A multi-buffer layer MBUF can be disposed on the second substrate SUB2, and a first active buffer layer ABUF1 can be disposed on the multi-buffer layer MBUF.

A first metal layer ML1 and a second metal layer ML2 can be disposed on the first active buffer layer ABUF1. For example, the first metal layer ML1 and the second metal layer ML2 can be light shield layers LS for shielding light.

A second active buffer layer ABUF2 can be disposed on the first metal layer ML1 and the second metal layer ML2. A first active layer ACT1 of the driving transistor DRT can be disposed on the second active buffer layer ABUF2.

A first gate insulating layer GI1 can be disposed such that the first gate insulating layer GI1 covers the first active layer ACT1.

A first gate electrode GATE1 of the driving transistor DRT can be disposed on the first gate insulating layer GI1. In an embodiment, a gate material layer GM can be disposed on the first gate insulating layer GI1, together with the first gate electrode GATE1 of the driving transistor DRT, at a location different from a location where the driving transistor DRT is disposed.

A first interlayer insulating layer ILD1 can be disposed on the first gate electrode GATE1 and the gate material layer GM such that the first interlayer insulating layer ILD1 covers the first gate electrode GATE1 and the gate material layer GM. A metal pattern TM1 can be disposed on the first interlayer insulating layer ILD1. The metal pattern TM1 can be located at a location different from the location where the driving transistor DRT is disposed. A second interlayer insulating layer ILD2 can be disposed on the metal pattern TM1 on the first interlayer insulating layer ILD1 such that the second interlayer insulating layer ILD2 covers the metal pattern TM1.

Two first source-drain electrode patterns SD1 can be disposed on the second interlayer insulating layer ILD2. One of the two first source-drain electrode patterns SD1 can be a source node of the driving transistor DRT, and the other thereof can be a drain node of the driving transistor DRT. The two first source-drain electrode patterns SD1 can be electrically connected to first and second portions (e.g., first and second side portions) of the first active layer ACT1, respectively, through contact holes formed in the second interlayer insulating layer ILD2, the first interlayer insulating layer ILD1, and the first gate insulating layer GI1.

A portion of the first active layer ACT1 overlapping with the first gate electrode GATE1 can be referred to as a channel region. One of the two first source-drain electrode patterns SD1 can be connected to a first portion (e.g., a first side portion) of the channel region of the active layer ACT1, and the other of the two first source-drain electrode patterns SD1 can be connected to a second portion (e.g., a second side portion) of the channel region of the active layer ACT1.

A passivation layer PAS0 can be disposed on the two first source-drain electrode patterns SD1 such that the passivation layer PAS0 covers the two first source-drain electrode patterns. A planarization layer PLN can be disposed on the passivation layer PAS0. The planarization layer PLN can include a first planarization layer PLN1 and a second planarization layer PLN2.

For example, the first planarization layer PLN1 can be disposed on the passivation layer PAS0.

A second source-drain electrode pattern SD2 can be disposed on the first planarization layer PLN1. The second source-drain electrode pattern SD2 can be connected to one of the two first source-drain electrode patterns SD1 (corresponding to the second node N2 of the driving transistor DRT in the subpixel SP of FIG. 3) through a contact hole formed in the first planarization layer PLN1.

The second planarization layer PLN2 can be disposed on the second source-drain electrode pattern SD2 such that the second planarization layer PLN2 covers the second source-drain electrode pattern SD2. A light emitting element ED of a subpixel SP can be disposed on the second planarization layer PLN2.

According to an example stack-up configuration of the light emitting element ED, an anode electrode AE can be disposed on the second planarization layer PLN2. The anode electrode AE can be electrically connected to the second source-drain electrode pattern SD2 through a contact hole formed in the second planarization layer PLN2.

A bank BANK can be disposed on the anode electrode AE such that the bank BANK covers a portion of the anode electrode AE. A portion of the bank BANK corresponding to the light emitting area EA of the subpixel SP can be opened.

A portion of the anode electrode AE can be exposed through the opening (the opened portion) of the bank BANK. An emitting material layer EML can be disposed on one or more side surfaces of the bank BANK and in the opening (the opened portion) of the bank BANK. All or at least part of the emitting material layer EML can be located between adjacent banks.

In the opening of the bank BANK, the emitting material layer EML can contact the anode electrode AE. A cathode electrode CE can be disposed on the emission layer EL.

The light emitting element ED can be formed by including the anode electrode AE, the emitting material layer EML, and the cathode electrode CE. The emitting material layer EML can include an organic material layer.

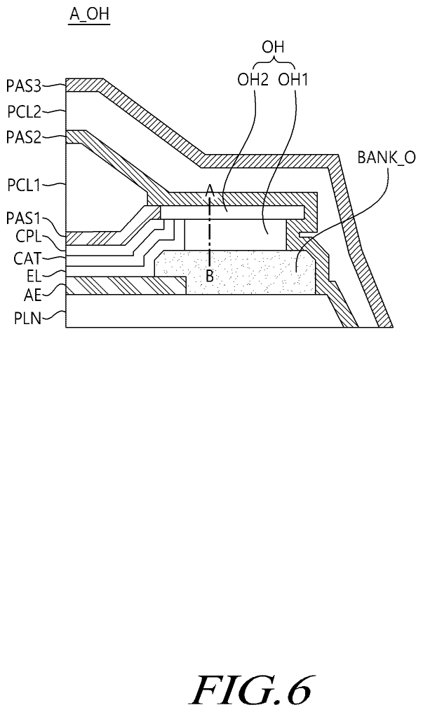

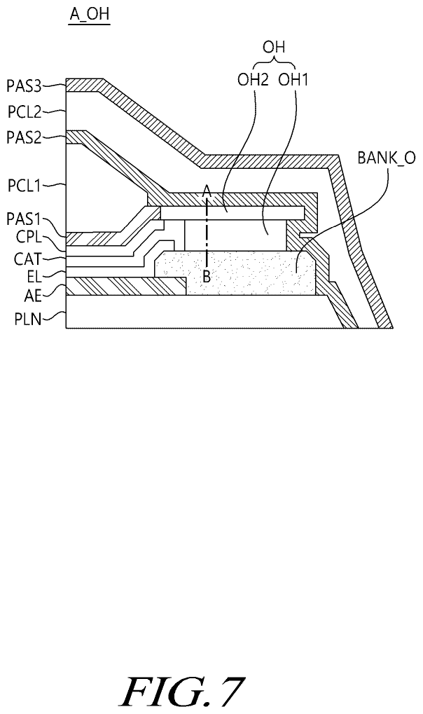

An encapsulation layer ENCAP can be disposed on the stack of the light emitting element ED. The encapsulation layer ENCAP can have a single-layer stack or a multi-layer stack. For example, as shown in FIGS. 6 and 7, the encapsulation layer ENCAP can include a first encapsulation layer PAS1, a second encapsulation layer PCL, and a third encapsulation layer PAS2.

The first encapsulation layer PAS1 and the third encapsulation layer PAS2 can be, for example, an inorganic material layer, and the second encapsulation layer PCL can be, for example, an organic material layer. Among the first encapsulation layer PAS1, the second encapsulation layer PCL, and the third encapsulation layer PAS2, the second encapsulation layer PCL can be the thickest and serve as a planarization layer.

The first encapsulation layer PAS1 can be disposed on the cathode electrode CE and can be disposed closest to the stack of the light emitting element ED. The first encapsulation layer PAS1 can include an inorganic insulating material capable of being deposited using low-temperature deposition. For example, the first encapsulation layer PAS1 can include, but not limited to, silicon nitride (SiNx), silicon oxide (SiOx), silicon oxynitride (SiON), aluminum oxide (Al2O3), or the like. Since the first encapsulation layer PAS1 can be deposited in a low temperature atmosphere, during the deposition process, the first encapsulation layer PAS1 can prevent the emitting material layer EML including an organic material vulnerable to a high temperature atmosphere from being damaged.

The second encapsulation layer PCL can have a smaller area or size than the first encapsulation layer PAS1. For example, the second encapsulation layer PCL can be disposed to expose both ends or edges of the first encapsulation layer PAS1. The second encapsulation layer PCL can serve as a buffer for relieving stress between corresponding layers while the display device 100 is curved or bent, and also serve to enhance planarization performance. For example, the second encapsulation layer PCL can include an organic insulating material, such as acrylic resin, epoxy resin, polyimide, polyethylene, silicon oxycarbon (SiOC), or the like. The second encapsulation layer PCL can be disposed, for example, using an inkjet technique.

The third encapsulation layer PAS2 can be disposed over the substrate SUB over which the second encapsulation layer PCL is disposed such that the third encapsulation layer PAS2 covers the respective top surfaces and side surfaces of the second encapsulation layer PCL and the first encapsulation layer PAS1. The third encapsulation layer PAS2 can minimize or prevent external moisture or oxygen from penetrating into the first encapsulation layer PAS1 and the second encapsulation layer PCL. For example, the third encapsulation layer PAS2 can include an inorganic insulating material, such as silicon nitride (SiNx), silicon oxide (SiOx), silicon oxynitride (SiON), aluminum oxide (Al2O3), or the like.

In an example where a touch sensor TS is embedded into the display panel PNL, the touch sensor TS can be disposed on the encapsulation layer ENCAP. The structure of the touch sensor will be described in detail as follows.

A touch buffer layer T-BUF can be disposed on the encapsulation layer ENCAP. The touch sensor TS can be disposed on the touch buffer layer T-BUF.

The touch sensor TS can include touch sensor metals TSM and at least one bridge metal BRG, which are located in different layers.

A touch interlayer insulating layer T-ILD can be disposed between the touch sensor metals TSM and the bridge metal BRG.

For example, the touch sensor metals TSM can include a first touch sensor metal TSM, a second touch sensor metal TSM, and a third touch sensor metal TSM, which are disposed adjacent to one another. In an embodiment where the third touch sensor metal TSM is disposed between the first touch sensor metal TSM and the second touch sensor metal TSM, and the first touch sensor metal TSM and the second touch sensor metal TSM are required to be electrically connected to each other, the first touch sensor metal TSM and the second touch sensor metal TSM can be electrically connected to each other through the bridge metal BRG located in a different layer. The bridge metal BRG can be electrically insulated from the third touch sensor metal TSM by the touch interlayer insulating layer T-ILD.

While the touch sensor TS is formed on the display panel PNL, a chemical solution (e.g., a developer or etchant) used in the corresponding process or moisture from the outside can be generated or introduced. In one or more embodiments, by disposing the touch sensor TS on the touch buffer layer T-BUF, a chemical solution or moisture can be prevented from penetrating into the emitting material layer EML including an organic material during the manufacturing process of the touch sensor TS. Accordingly, the touch buffer layer T-BUF can prevent damage to the emitting material layer EML, which is vulnerable to a chemical solution or moisture.

In order to prevent damage to the emitting material layer EML including an organic material, which is vulnerable to high temperatures, the touch buffer layer T-BUF can be formed at a low temperature less than or equal to a predetermined temperature (e.g., 100 degrees (° C.)) and be formed using an organic insulating material having a low permittivity of 1 to 3. For example, the touch buffer layer T-BUF can include an acrylic-based, epoxy-based, or siloxan-based material. As the display device 100 is bent, the encapsulation layer ENCAP can be damaged, and the touch sensor metal located on the touch buffer layer T-BUF can be cracked or broken. Even when the display device 100 is bent, the touch buffer layer T-BUF having the planarization performance as the organic insulating material can prevent the damage of the encapsulation layer ENCAP and/or the cracking or breaking of the metals (TSM, BRG) included in the touch sensor TS.

A protective layer PAC can be disposed on the touch sensor TS such that the protective layer PAC covers the touch sensor TS. The protective layer PAC can be, for example, an organic insulating layer.

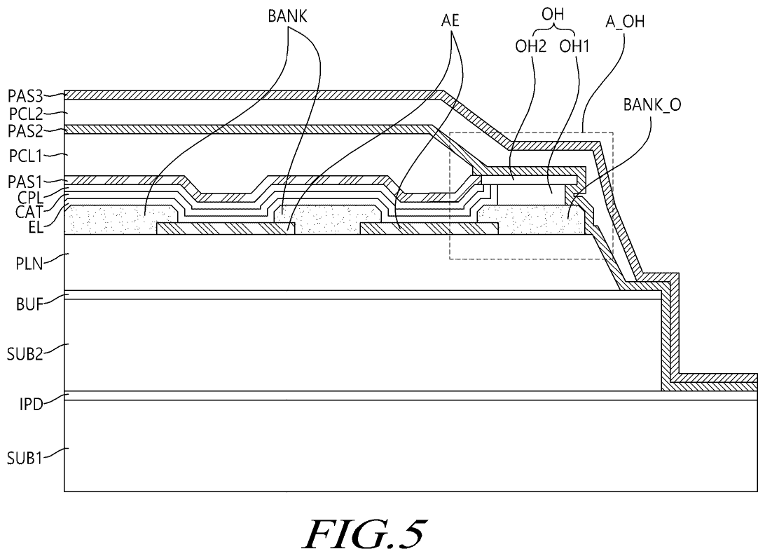

FIG. 5 illustrates an example overhang structure OH in the display panel 110 according to aspects of the present disclosure.

Referring to FIG. 5, the display device 100 can include a substrate SUB1 including a display area and a dam area surrounding the display area, a planarization layer PLN disposed on the substrate SUB1, a light emitting element intermediate layer EL (i.e., an emission layer) disposed on the planarization layer PLN in the display area, an outermost bank BANK_O disposed on the planarization layer PLN in the dam area, a first overhang structure OH1 disposed to overlap with the outermost bank BANK_O, and a second overhang structure OH2 disposed to overlap with the first overhang structure OH1.

The overhang structure OH can include the first overhang structure OH1 and the second overhang structure OH2. As the display device 100 includes the overhang structure OH, a structure in which a portion of the light emitting element intermediate layer EL is cut off from the remaining portion of the light emitting element intermediate layer EL can be easily formed. Further, as the display device 100 includes the overhang structure OH, the penetration of moisture or oxygen into the display panel 110 can be effectively prevented. This overhang structure OH will be discussed in detail below.

The display panel 110 shown in FIG. 5 can be the same as the display panel 110 shown in FIG. 4. In order to illustrate the overhang structure OH in detail, some of the components in the cross-sectional view of the display panel 110 shown in FIG. 4 are omitted in FIG. 5. For example, components disposed between the second substrate SUB2 and the anode layer AE shown in FIG. 4 are omitted in FIG. 5. In addition, a transistor under an anode layer AE and elements related to the transistor are omitted as in the cross-sectional view of the display panel 110 shown in FIG. 5. Hereinafter, the stackup configuration of the display panel 110 will be discussed starting from the first substrate SUB1 with reference to FIGS. 4 and 5.

The first substrate SUB1 can be disposed at the bottom of the display panel 110. The first substrate SUB1 can be the same as the first substrate SUB1 shown in FIG. 4.

An interlayer insulating layer IPD can be disposed on the first substrate SUB1. The interlayer insulating layer IPD can be the same as the interlayer insulating layer IPD shown in FIG. 4.

A second substrate SUB2 can be disposed on the interlayer insulating layer IPD. The second substrate SUB1 can be disposed such that the second substrate SUB1 exposes a portion of the first substrate SUB1. Referring to FIGS. 3 and 5, a right portion of the first substrate SUB1 can extend beyond a right end of the second substrate SUB2. The second substrate SUB2 can be the same as the second substrate SUB2 shown in FIG. 4.

At least one buffer layer BUF can be disposed on the second substrate SUB2. The buffer layer BUF can include the multi buffer layer MBUF and the active buffer layers (ABUF1 and ABUF2) shown in FIG. 4.

The planarization layer PLN can be disposed on the buffer layer BUF. The planarization layer PLN can include the planarization layer (PLN) shown in FIG. 4. The planarization layer PLN can be formed from two or three or more planarization layers PLN. The planarization layer PLN can include a contact hole, and upper and lower electrodes disposed in different layers can be electrically connected through the contact hole.

The anode layer AE can be disposed on the planarization layer PLN. The anode layer AE is deposited on the top of the planarization layer PLN, and thereafter, the anode layer AE can be patterned to form an electrode. Thus, the anode layer can also be referred to an anode electrode AE. One or more respective elements included in a plurality of transistors such as a driving transistor, and the like can be disposed in (or on or under) the planarization layer PLN. The source electrode (or drain electrode) of the driving transistor can be electrically connected to the anode electrode AE. The anode electrode AE shown in FIG. 5 can have the same characteristics as the anode electrode AE shown in FIG. 4. Discussions for one or more elements of the transistor electrically connected to the anode electrode AE shown in FIG. 5 are omitted for convenience of explanation.

A bank BANK can be disposed on the planarization layer PLN and the anode layer AE.

The outermost bank BANK_O can be disposed on the planarization layer PLN, and for example, be disposed adjacent to an edge of the planarization layer PLN. The outermost bank BANK_O can prevent an organic encapsulation layer from overflowing to the outside.

The overhang structure OH can include the first overhang structure OH1 and the second overhang structure OH2. The first overhang structure OH1 and the second overhang structure OH2 can each surround the display area.

The first overhang structure OH1 can be disposed on the outermost bank BANK_O. The first overhang structure OH1 can include an inner side (for example, the left surface shown in FIGS. 5 to 8 and 10 to 12) facing towards the display area, an outer side (for example, the right surface shown in FIGS. 5 to 8 and 10 to 12) opposite to the inner side and facing away from the display area, and a top surface and a bottom surface each extending between the inner side and the outer side. The bottom surface of the first overhang structure OH1 can face towards the first substrate SUB1 and the outermost bank BANK_O, and the top surface of the first overhang structure OH1 can face away from the first substrate SUB1 and the outermost bank BANK_O.

The second overhang structure OH2 can be disposed on the first overhang structure OH1. The second overhang structure OH2 can include an inner side (for example, the left surface shown in FIGS. 5 to 8 and 10 to 12) facing towards the display area, an outer side (for example, the right surface shown in FIGS. 5 to 8 and 10 to 12) opposite to the inner side and facing away from the display area, and a top surface and a bottom surface each extending between the inner side and the outer side. The bottom surface of the second overhang structure OH2 can face towards the first substrate SUB1, the outermost bank BANK_O, and the first overhang structure OH1, and the top surface of the second overhang structure OH2 can face away from the first substrate SUB1, the outermost bank BANK_O, and the first overhang structure OH1. The second overhang structure OH2 can include a first extension portion extending beyond the first overhang structure OH1 in a lateral inward direction towards the display area and a second extension portion extending beyond the first overhang structure OH1 in a lateral outward direction away from the display area.

A width of the second overhang structure OH2 (i.e., a distance between left and right ends of the second overhang structure OH2) can be greater than that of the first overhang structure OH1 (i.e., a distance between left and right ends of the first overhang structure OH1. The width of the second overhang structure OH2 can be a dimension between the inner side and the outside thereof along a lateral direction which can be substantially parallel to the first substrate SUB1. The width of the first overhang structure OH1 can be a dimension between the inner side and the outside thereof along the lateral direction.

As the overhang structure OH is disposed, one or more layers deposited on the overhang structure OH can be disposed in a form in which a respective portion of the one or more layers is cut off from the respective remaining portion of the one or more layers.

The light emitting element intermediate layer EL can be disposed on the bank BANK. The light emitting element intermediate layer EL can be disposed on the bank BANK and contact the anode electrode AE.

Referring to FIG. 5, the light emitting element intermediate layer EL can be disposed such that the light emitting element intermediate layer EL contacts two anode electrodes AE. As the overhang structure OH is disposed, the light emitting element intermediate layer EL can be disposed in a form in which a portion of the light emitting element intermediate layer EL is cut off from the remaining portion of the light emitting element intermediate layer EL. For example, the light emitting element intermediate layer EL can be disposed only up to the left side of the first overhang structure OH1. The light emitting element intermediate layer EL can extend from the display area to the dam area and terminate at the inner side of the first overhang structure OH1 (i.e., the left side thereof shown in FIG. 5). As will be described below, the light emitting element intermediate layer EL can contact with the inner side of the first overhang structure OH1 or can be spaced apart from the inner side of the first overhang structure OH1.

A cathode layer CAT can be disposed on the light emitting element intermediate layer EL. As the overhang structure OH is disposed, the cathode layer CAT can be disposed in a form in which a portion of the cathode layer CAT is cut off from the remaining portion of the cathode layer CAT. For example, the cathode layer CAT can be disposed only up to the left side of the first overhang structure OH1 or the left side of the light emitting element intermediate layer EL contacting the left surface of the first overhang structure OH1. The cathode layer CAT can extend from the display area to the dam area and terminate at the inner side of the first overhang structure OH1 (i.e., the left side thereof shown in FIG. 5). As will be described below, the cathode layer CAT can contact with the inner side of the first overhang structure OH1 or can be spaced apart from the inner side of the first overhang structure OH1.

A capping layer CPL can be disposed on the cathode layer CAT. For example, the capping layer CPL can be disposed only up to the left side of the first overhang structure OH1 or the left side of the cathode layer CAT contacting the left surface of the light emitting element intermediate layer EL contacting the left surface of the first overhang structure OH1. The capping layer CPL can extend from the display area to the dam area and terminate at the inner side of the first overhang structure OH1 (i.e., the left side thereof shown in FIG. 5). The capping layer CPL can contact with the inner side of the first overhang structure OH1 or can be spaced apart from the inner side of the first overhang structure OH1.

A first encapsulation layer PAS1 can be disposed on the capping layer CPL. The first encapsulation layer PAS1 can be an inorganic encapsulation layer. The first encapsulation layer PAS1 can be disposed only up to the left side of the first or second overhang structure OH1 or OH2.

The second encapsulation layer PCL1 can be disposed on the first encapsulation layer PAS1. The second encapsulation layer PCL1 can be disposed on the left side of the second overhang structure OH2. For example, the second encapsulation layer PCL1 can be disposed up to a location spaced apart by a certain distance from a left edge (i.e., an inner side edge) of the second overhang structure OH2. The second encapsulation layer PCL1 can be an organic encapsulation layer. As the outermost bank BANK_O and the overhang structure OH are disposed on the right side of the second encapsulation layer PCL1, the second encapsulation layer PCL1, which is an organic encapsulation layer, may not overflow into the non-display area. A portion of the upper surface of the second encapsulation layer PCL1, which corresponds to the display area, can be disposed to be flat, and another portion of the upper surface of the second encapsulation layer PCL1 can be inclined downwardly as the another portion of the upper surface of the second encapsulation layer PCL1 extends closer to the non-display area.

A third encapsulation layer PAS2 can be disposed on the second encapsulation layer PCL1. The third encapsulation layer PAS2 can be an inorganic encapsulation layer. The third encapsulation layer PAS2 can include an inorganic material. The third encapsulation layer PAS2 can be disposed such that the third encapsulation layer PAS2 covers the overhang structure OH and the non-display area.

A fourth encapsulation layer PCL2 can be disposed on the third encapsulation layer PAS2. The fourth encapsulation layer PCL2 can be an organic encapsulation layer. The fourth encapsulation layer PCL2 can be disposed such that the fourth encapsulation layer PCL2 covers the overhang structure OH and the non-display area.

A fifth encapsulation layer PAS3 can be disposed on the fourth encapsulation layer PCL2. The fifth encapsulation layer PAS3 can be an inorganic encapsulation layer. The fifth encapsulation layer PAS3 can be disposed such that the fifth encapsulation layer PAS3 covers the overhang structure OH and the non-display area.

When the fourth encapsulation layer PCL2 and the fifth encapsulation layer PAS3 are disposed on the third encapsulation layer PAS2, the penetration of external moisture or oxygen can be prevented more effectively. In an embodiment, an additional encapsulation layer can be disposed on the fifth encapsulation layer PAS3.

FIG. 5 illustrates the overhang structure OH as discussed above. Hereinafter, the overhang structure OH according to aspects of the present disclosure will be described in more detail.

FIGS. 6, 7, and 8 are cross-sectional views of various examples of the overhang structure OH configured in the display panel 110 according to aspects of the present disclosure.

Referring to FIGS. 5 and 6, the first overhang structure OH1 can be disposed on an outermost bank BANK_O. A width of the first overhang structure OH1 (i.e., a distance between left and right ends of the first overhang structure OH1) can be less than a width of the outermost bank BANK_O (i.e., a distance between left and right ends of the outermost bank BANK_O). The center of the first overhang structure OH1 can correspond to the center of the outermost bank BANK_O. The center of the second overhang structure OH2 can correspond to the center of the outermost bank BANK_O and/or the center of the first overhang structure OH1.

The first overhang structure OH1 can be disposed such that the first overhang structure OH1 contacts a light emitting element intermediate layer EL. The left surface (i.e., the inner side) of the first overhang structure OH1 can contact the light emitting element intermediate layer EL.

The second overhang structure OH2 can be disposed such that the second overhang structure OH2 contacts a light emitting element intermediate layer EL and a cathode layer CAT. The bottom surface of the second overhang structure OH2 can contact the light emitting element intermediate layer EL. The bottom surface of the second overhang structure OH2 can contact the cathode layer CAT.

As the display device 100 includes the overhang structure OH, a structure in which a portion of the light emitting element intermediate layer EL is cut off from the remaining portion of the light emitting element intermediate layer EL can be easily formed. Further, as the display device 100 includes the overhang structure OH, the penetration of moisture or oxygen into the display panel 110 can be effectively prevented.

The second overhang structure OH2 can include an electrically conductive material such as a metal. In this example, the second overhang structure OH2 can be formed from a material capable of conducting electricity. The second overhang structure OH2 can be disposed such that the second overhang structure OH2 contacts the cathode layer CAT. In this implementation, the second overhang structure OH2 can be electrically connected to the cathode layer CAT. The second overhang structure OH2 can serve as an auxiliary cathode layer, and the second overhang structure OH2 can include both structural and electrical characteristics. The second overhang structure OH2 serving as the auxiliary cathode layer can reduce a resistance of the cathode layer CAT. As the cathode layer CAT is electrically connected to the second common driving voltage line VSSL, a resistance of the second common driving voltage line VSSL can be reduced, thereby reducing a voltage drop of the second common driving voltage VSS. This reduces the power consumption of the display device 100.

The light emitting element intermediate layer EL can be disposed such that the light emitting element intermediate layer EL contacts the first overhang structure OH1 on the left side of the first overhang structure OH1. The second overhang structure OH2 can be disposed such that at least one of side portions of the second overhang structure OH2 extends beyond at least one of side ends of the first overhang structure OH1 (i.e., the extension portion of the second overhang structure OH2 are exposed from the first overhang structure OH1). For example, the extension portion of the second overhang structure OH2 can contact the light emitting element intermediate layer EL. For example, a portion of the bottom surface of the second overhang structure OH2 can contact the light emitting element intermediate layer EL.

The cathode layer CAT can be disposed such that the cathode layer CAT covers the light emitting element intermediate layer EL. The extension portion of the second overhang structure OH2 exposed from the first overhang structure OH1 can contact the cathode layer CAT. For example, a portion of the bottom surface of the second overhang structure OH2 can contact the cathode layer CAT. The second overhang structure OH2 can include a first extension portion extending beyond the first overhang structure OH1 in a lateral inward direction towards the display area. The first extension portion can include a bottom surface facing towards the first substrate SUB1. The cathode layer CAT can contact the bottom surface of the first extension portion. As described above, the light emitting element intermediate layer EL can contact both the bottom surface of the first extension portion of the second overhang structure OH2 and the inner side of the first overhang structure OH1. In this case, the cathode layer CAT can be spaced apart from the inner side of the first overhang structure OH1 by the light emitting element intermediate layer EL.

A third encapsulation layer PAS2 can be disposed such that the third encapsulation layer PAS2 covers the second overhang structure OH2. The third encapsulation layer PAS2 can be disposed on the second encapsulation layer PCL1 and extend from the display area to the dam area. The third encapsulation layer PAS2 can cover a top surface of the second overhang structure OH2 facing away from the substrate, an outer side of the second overhang structure OH2 opposite to the inner side thereof, an outer side of the first overhang structure OH1 opposite to the inner side thereof, and an outer side of the outermost bank BANK_O.

A fourth encapsulation layer PCL2 can be disposed such that the fourth encapsulation layer PCL2 covers the third encapsulation layer PAS2. The fourth encapsulation layer PCL2 can be an organic encapsulation layer.

A fifth encapsulation layer PAS3 can be disposed such that the fifth encapsulation layer PAS3 covers the fourth encapsulation layer PCL2. The fifth encapsulation layer PAS3 can be an inorganic encapsulation layer.

The fourth encapsulation layer PCL2 and the fifth encapsulation layer PAS3 can be disposed such that the fourth encapsulation layer PCL2 and the fifth encapsulation layer PAS3 overlap with the overhang structure OH.

Hereinafter, the overhang structure OH of FIG. 7 will be described.

Referring to FIGS. 5 and 7, the first overhang structure OH1 can be disposed on an outermost bank BANK_O. A width of the first overhang structure OH1 (i.e., a distance between left and right ends of the first overhang structure OH1) can be less than a width of the outermost bank BANK_O (i.e., a distance between left and right ends of the outermost bank BANK_O). The center of the first overhang structure OH1 can correspond to the center of the outermost bank BANK_O.

A cathode layer CAT can be disposed between a light emitting element intermediate layer EL and the first overhang structure OH1, and the light emitting element intermediate layer EL can be disposed such that the light emitting element intermediate layer EL is spaced apart from the first overhang structure OH1. A portion of the light emitting element intermediate layer EL can overlap with the cathode layer CAT and the second overhang structure OH2.

The light emitting element intermediate layer EL can be disposed such that the light emitting element intermediate layer EL covers an anode electrode AE and a portion of the outermost bank BANK_O.

Referring to FIG. 7, the cathode layer CAT can be disposed such that the cathode layer CAT covers the light emitting element intermediate layer EL.

The cathode layer CAT can be disposed such that the cathode layer CAT contacts the first overhang structure OH1. The left surface (i.e., the inner side) of the first overhang structure OH1 can contact the cathode layer CAT.

The cathode layer CAT can be disposed such that the cathode layer CAT contacts the second overhang structure OH2. The bottom surface of the second overhang structure OH2 can contact the cathode layer CAT. The extension portion of the second overhang structure OH2 exposed from the first overhang structure OH1 can contact the cathode layer CAT. For example, a portion of the bottom surface of the second overhang structure OH2 can contact the cathode layer CAT. The cathode layer CAT can include a first extension portion extending beyond the first overhang structure OH1 in a lateral inward direction towards the display area. The first extension portion can include a bottom surface facing towards the first substrate SUB1. The cathode layer CAT can contact the bottom surface of the first extension portion.

As the display device 100 includes the overhang structure OH, a structure in which a portion of the light emitting element intermediate layer EL is cut off from the remaining of the light emitting element intermediate layer EL can be easily formed. Further, as the display device 100 includes the overhang structure OH, the penetration of moisture or oxygen into the display panel 110 can be effectively prevented.

The first overhang structure OH1 can include an electrically conductive material such as a metal. In this example, the first overhang structure OH1 can be formed from a material capable of conducting electricity. The first overhang structure OH1 can be disposed such that the first overhang structure OH1 contacts the cathode layer CAT. In this implementation, the first overhang structure OH1 can be electrically connected to the cathode layer CAT. The first overhang structure OH1 can serve as an auxiliary cathode layer, and the first overhang structure OH1 can include both structural and electrical characteristics. The first overhang structure OH1 serving as the auxiliary cathode layer can reduce a resistance of the cathode layer CAT. As the cathode layer CAT is electrically connected to the second common driving voltage line VSSL, a resistance of the second common driving voltage line VSSL can be reduced, thereby reducing a voltage drop of the second common driving voltage VSS. This reduces the power consumption of the display device 100. Alternatively, or additionally, the second overhang structure OH2 can include an electrically conductive material such as a metal. In this example, the second overhang structure OH2 can be formed from a material capable of conducting electricity. The second overhang structure OH2 can be disposed such that the second overhang structure OH2 contacts the cathode layer CAT. In this implementation, the second overhang structure OH2 can be electrically connected to the cathode layer CAT. The second overhang structure OH2 can serve as an auxiliary cathode layer, and the second overhang structure OH2 can include both structural and electrical characteristics.

Referring to FIGS. 5 and 7, a third encapsulation layer PAS2 can be disposed such that the third encapsulation layer PAS2 covers the second overhang structure OH2. The third encapsulation layer PAS2 can be disposed on the second encapsulation layer PCL1 and extend from the display area to the dam area. The third encapsulation layer PAS2 can cover a top surface of the second overhang structure OH2 facing away from the substrate, an outer side of the second overhang structure OH2 opposite to the inner side thereof, an outer side of the first overhang structure OH1 opposite to the inner side thereof, and an outer side of the outermost bank BANK_O.

A fourth encapsulation layer PCL2 and a fifth encapsulation layer PAS3 can be disposed such that the fourth encapsulation layer PCL2 and the fifth encapsulation layer PAS3 overlap with the overhang structure OH.

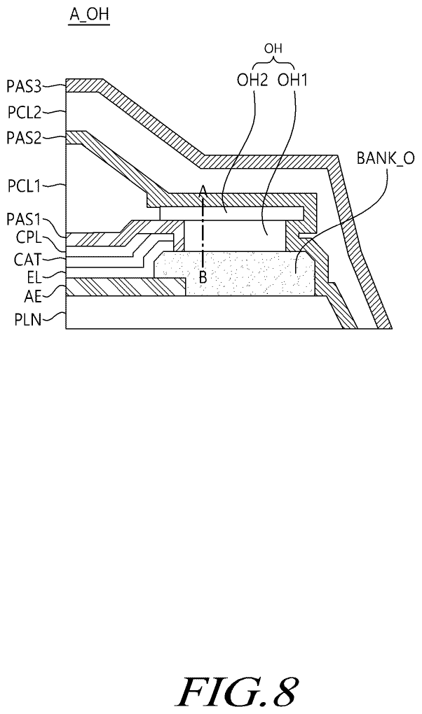

Hereinafter, the overhang structure OH of FIG. 8 according to an aspect of the present disclosure will be described.

Referring to FIGS. 5 and 8, the first overhang structure OH1 can be disposed on an outermost bank BANK_O. A width of the first overhang structure OH1 (i.e., a distance between left and right ends of the first overhang structure OH1) can be less than a width of the outermost bank BANK_O (i.e., a distance between left and right ends of the outermost bank BANK_O). The center of the first overhang structure OH1 can correspond to the center of the outermost bank BANK_O.

The first overhang structure OH1 can be disposed such that the first overhang structure OH1 is spaced apart from a light emitting element intermediate layer EL.

The first encapsulation layer PAS1 can extend from the display area to the dam area and terminate at the inner side of the first overhang structure OH1 (i.e., the left side thereof shown in FIG. 5). A side surface of the first overhang structure OH1 and the bottom surface of the second overhang structure OH2 can be disposed such that the side surface of the first overhang structure OH1 and the bottom surface of the second overhang structure OH2 contact a first encapsulation layer PAS1. The first encapsulation layer PAS1 can be disposed on a capping layer CPL such that the first encapsulation layer PAS1 covers a side surface of a cathode layer CAT and a side surface of the light emitting element intermediate layer EL.

Referring to FIG. 8, the first overhang structure OH1 can be disposed such that the first overhang structure OH1 is spaced apart from the cathode layer CAT. The first encapsulation layer PAS1 can be disposed on a side surface of the first overhang structure OH1, and the cathode layer CAT can be leftwardly spaced apart from the side surface of the first overhang structure OH1.

The first overhang structure OH1 can be disposed such that the first overhang structure OH1 is spaced apart from the capping layer CPL. The first encapsulation layer PAS1 can be disposed on the side surface of the first overhang structure OH1, and the capping layer CPL can be leftwardly spaced apart from the side surface of the first overhang structure OH1.

The first overhang structure OH1 can be disposed such that the first overhang structure OH1 contacts the first encapsulation layer PAS1.

The first encapsulation layer PAS1 can be disposed such that the first encapsulation layer PAS1 contacts the side surface of the first overhang structure OH1.

The second overhang structure OH2 can be disposed such that the second overhang structure OH2 is spaced apart from the light emitting element intermediate layer EL.

The second overhang structure OH2 can be disposed such that the second overhang structure OH2 is spaced apart from the cathode layer CAT. Referring to FIG. 8, the first encapsulation layer PAS1 can be disposed on the bottom surface of the second overhang structure OH2, and the cathode layer CAT can be disposed such that the cathode layer CAT is downwardly spaced apart from the bottom surface of the second overhang structure OH2.

The second overhang structure OH2 can be disposed such that the second overhang structure OH2 is spaced apart from the capping layer CPL. Referring to FIG. 8, the first encapsulation layer PAS1 can be disposed on the bottom surface of the second overhang structure OH2, and the cathode layer CAT can be disposed such that the cathode layer CAT is downwardly spaced apart from a left portion of the bottom surface of the second overhang structure OH2.

The second overhang structure OH2 can be disposed such that the second overhang structure OH2 contacts the first encapsulation layer PAS1.

The first encapsulation layer PAS1 can be disposed such that the first encapsulation layer PAS1 contacts the bottom surface of the second overhang structure OH2.

The top surface of the second overhang structure OH2 can be higher than the top surface of the first encapsulation layer PAS1 in the cross-sectional view of FIG. 8.

The first encapsulation layer PAS1 can be disposed such that the first encapsulation layer PAS1 covers the light emitting element intermediate layer EL and the cathode layer CAT. As the first encapsulation layer PAS1 covers the light emitting element intermediate layer EL and the cathode layer CAT, the penetration of moisture or oxygen into the emission EL can be effectively prevented.

A side surface of the first overhang structure OH1 and a portion of the bottom surface of the second overhang structure OH2 can be disposed such that the side surface of the first overhang structure OH1 and the portion of the bottom surface of the second overhang structure OH2 contact the first encapsulation layer PAS1. The first encapsulation layer PAS1 can be disposed such that the first encapsulation layer PAS1 contacts the side surface of the first overhang structure OH1 and overlaps with the second overhang structure OH2. The first encapsulation layer PAS1 can be disposed underneath an extension portion of the second overhang structure OH2, which extends beyond a side end of the first overhang structure OH1.

A portion of the first encapsulation layer PAS1 can be disposed between a side surface of the light emitting element intermediate layer EL and a side surface of the first overhang structure OH1.

A portion of the first encapsulation layer PAS1 can be disposed between a side surface of the cathode layer CAT and the side surface of the first overhang structure OH1. The second encapsulation layer PCL1 can be disposed on the first encapsulation layer PAS1 and extend from the display area to the dam area. The second encapsulation layer PCL1 can terminate at the inner side of the second overhang structure OH2 facing towards the display area and contact with the inner side of the second overhang structure OH2.

Referring to FIGS. 5 and 8, the third encapsulation layer PAS2 can be disposed such that the third encapsulation layer PAS2 covers the second overhang structure OH2. The third encapsulation layer PAS2 can be disposed on the second encapsulation layer PCL1 and extend from the display area to the dam area. The third encapsulation layer PAS2 can cover a top surface of the second overhang structure OH2 facing away from the substrate, an outer side of the second overhang structure OH2 opposite to the inner side thereof, an outer side of the first overhang structure OH1 opposite to the inner side thereof, and an outer side of the outermost bank BANK_O.

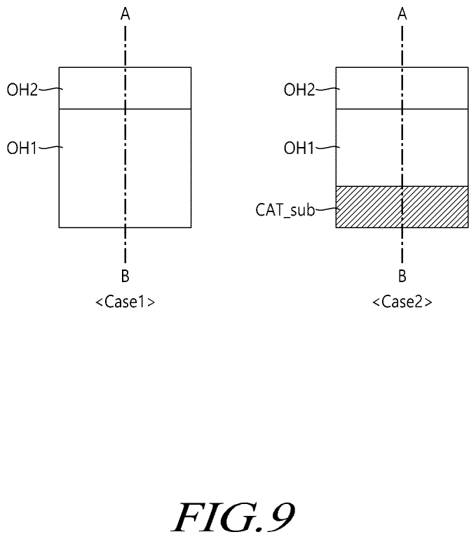

FIGS. 6, 7, and 8 show respective areas including line A-B. Example areas including line A-B will be described with reference to FIG. 9.

FIG. 9 illustrates areas where the overhang structure is configured in the display panel 110 according to aspects of the present disclosure. Particularly, FIG. 9 illustrates a first example and a second example of the overhand structure.

Referring to the first example of FIG. 9 (Case 1), the overhang structure OH can include the first overhang structure OH1 and the second overhang structure OH2. For example, the first overhang structure OH1 can include silicon oxide, and the second overhang structure OH2 can include one or more metal particles. In another example, the first overhang structure OH1 can include one or more metal particles, and the second overhang structure OH2 can include amorphous silicon.

Referring to the second example of FIG. 9 (Case 2), the overhang structure OH can include the first overhang structure OH1, the second overhang structure OH2, and an auxiliary cathode layer CAT_sub. In some embodiments, the auxiliary cathode layer CAT_sub shown in FIG. 9 can be disposed in the areas including line A-B of FIGS. 6, 7, and 8. In these embodiments, the auxiliary cathode layer CAT_sub can be disposed between the first overhang structure OH1 and the outermost bank BANK_O. The auxiliary cathode layer CAT_sub can be electrically connected to the cathode layer CAT. As an example, the cathode layer CAT can contact the auxiliary cathode layer CAT_sub and thus can be electrically connected to the auxiliary cathode layer CAT_sub. As another example, the cathode layer CAT can contact the first overhang structure OH1 and thus can be electrically connected to the auxiliary cathode layer CAT_sub by the first overhang structure OH1 which is capable of conducting electricity. As yet another example, the cathode layer CAT can contact the second overhang structure OH2 and can be electrically connected to the auxiliary cathode layer CAT_sub by the second overhang structure OH2 and the first overhang structure OH1 which are capable of conducting electricity. Therefore, the auxiliary cathode layer CAT_sub can assist the function of the cathode layer CAT configured to receive a base voltage. Electrically connecting the cathode layer CAT to the auxiliary cathode layer CAT_sub can reduce a resistance of the cathode layer CAT. As the cathode layer CAT is electrically connected to the second common driving voltage line VSSL, a resistance of the second common driving voltage line VSSL can be reduced, thereby reducing a voltage drop of the second common driving voltage VSS (i.e., the base voltage). This reduces the power consumption of the display device 100.

In the second example of FIG. 9, the first overhang structure OH1 can include silicon oxide, and the second overhang structure OH2 can include amorphous silicon. In this implementation, the auxiliary cathode layer CAT_sub can include metal or a metal alloy. The auxiliary cathode layer CAT_sub can include one or more metal particles, such as silver (Ag), aluminum (Al), molybdenum (Mo), titanium (Ti), copper (Cu), gold (Au), magnesium (Mg), calcium (Ca), or barium (Ba). However, these metal particles are merely examples containable in the auxiliary cathode layer CAT_sub, and therefore, embodiments of the present disclosure are not limited thereto.

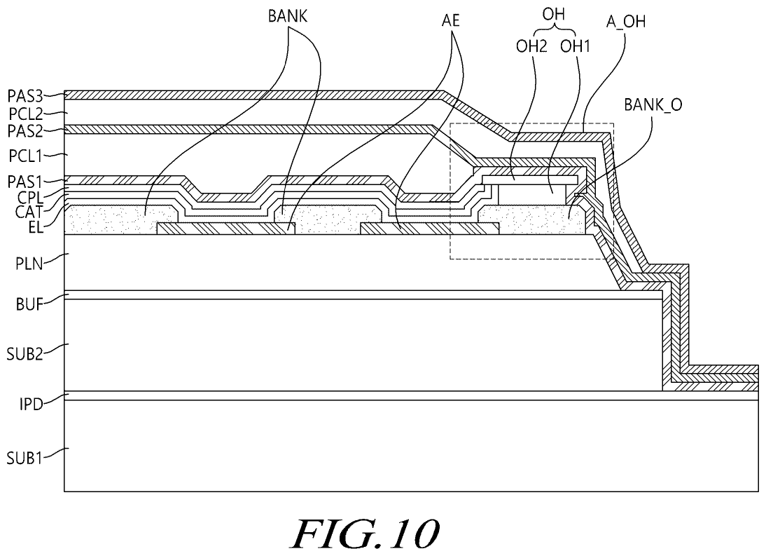

FIG. 10 illustrates an example cross-sectional view of the display panel 110 with an overhang structure according to aspects of the present disclosure.

Referring to FIG. 10, a first encapsulation layer PAS1 can be disposed such that the first encapsulation layer PAS1 covers the overhang structure OH, which is different from the arrangement of the first encapsulation layer PAS1 included in the display panel 110 shown in FIG. 5. The first encapsulation layer PAS1 can be disposed such that the first encapsulation layer PAS1 covers the top surface of the second overhang structure OH2.

The first encapsulation layer PAS1 can be disposed such that the first encapsulation layer PAS1 covers the right surface (i.e., the outer side) of the second overhang structure OH2 and the right surface (i.e., the outer side) of the first overhang structure OH1. Thus, the first encapsulation layer PAS1 can contact the right surface (i.e., the outer side) of the first overhang structure OH1. A light emitting element intermediate layer EL can be disposed such that the light emitting element intermediate layer EL contacts the left surface (i.e., the inner side) of the first overhang structure OH1.

The first encapsulation layer PAS1 can be disposed such that the first encapsulation layer PAS1 contacts a right portion (i.e., the outer portion) of the bottom surface of the second overhang structure OH2 and contacts the right surface (i.e., the outer side) of the first overhang structure OH1.

As the first encapsulation layer PAS1 is disposed such that the first encapsulation layer PAS1 covers all of the overhang structure OH, the overhang structure OH can be protected from external substances.

In addition, as the first encapsulation layer PAS1 is disposed such that the first encapsulation layer PAS1 covers all of the overhang structure OH, the first encapsulation layer PAS1 can prevent the overhang structure OH from being deformed. The first encapsulation layer PAS1 can prevent deformation of the overhang structure OH during the manufacturing process of the display device 100.

The first encapsulation layer PAS1 can be disposed such that the first encapsulation layer PAS1 covers all of a first substrate SUB1, an interlayer insulating film IPD, a second substrate SUB2, a buffer layer BUF, and a planarization layer PLN, as well as the overhang structure OH. The second encapsulation layer PCL1 can be disposed on the first encapsulation layer PAS1 and extend from the display area to the dam area, the second encapsulation layer PCL1 can terminate at the inner side of the second overhang structure OH2 and can be spaced apart from the inner side of the second overhang structure OH2 by the first encapsulation layer PAS1.

A third encapsulation layer PAS2 can be disposed such that the third encapsulation layer PAS2 covers the first encapsulation layer PAS1 while being located on the overhang structure OH. Referring to FIG. 10, the third encapsulation layer PAS2 can be disposed such that the third encapsulation layer PAS2 covers the first encapsulation layer PAS1 in a rightward direction relative to the overhang structure OH.

A fifth encapsulation layer PAS3 can be disposed such that the fifth encapsulation layer PAS3 covers the third encapsulation layer PAS2 in a rightward direction relative to the overhang structure OH.

Hereinafter, example cross-sectional views of the display panel 110 showing the overhang structure OH and a transistor structure according to aspects of the present disclosure will be described.

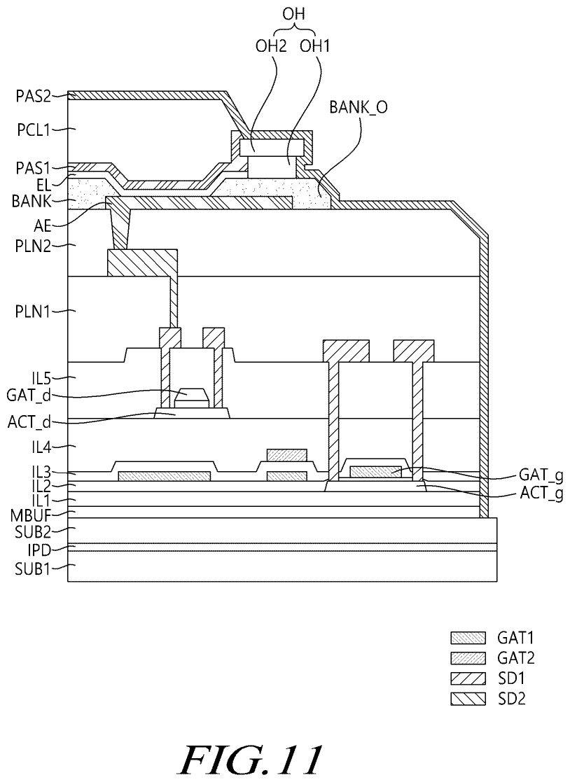

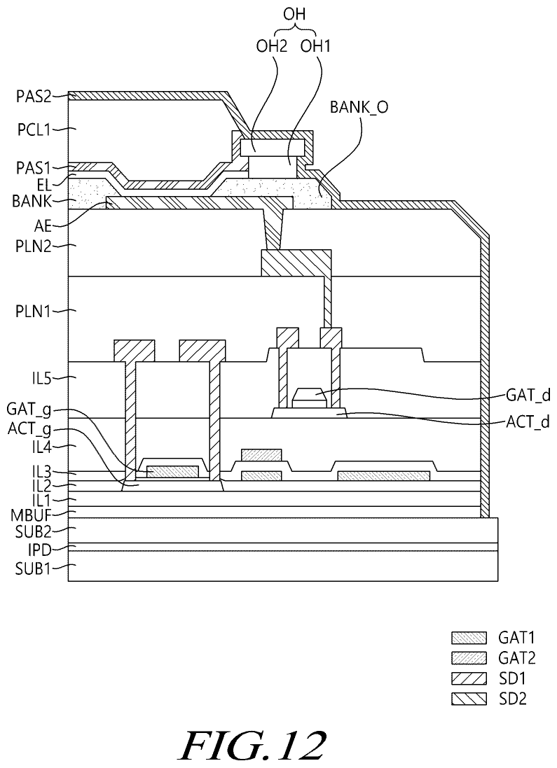

FIGS. 11 and 12 are example cross-sectional views of the display panel 110 according to aspects of the present disclosure.

Referring to FIG. 11, a substrate SUB can include a first substrate SUB1, a second substrate SUB2, and an interlayer insulating layer IPD interposed between the first and second substrates SUB1 and SUB2.

A transistor layer can be disposed on the substrate SUB. The transistor layer can be a layer in which a driving transistor and a transistor of a gate driving circuit are disposed.

The transistor layer can include a multi-buffer layer MBUF, a first insulating layer IL1, a second insulating layer IL2, a third insulating layer IL3, a fourth insulating layer IL4, a fifth insulating layer IL5, and a first planarization layer PLN1.

A first active layer ACT_g can be disposed on the first insulating layer IL1. The first active layer ACT_g can include low-temperature polycrystalline silicon (LTPS). A transistor including the first active layer ACT_g can be an LTPS thin film transistor (TFT).

The second insulating layer IL2 can be disposed such that the second insulating layer IL2 covers the first active layer ACT_g.

First gate electrodes GAT1 can be disposed on the second insulating layer IL2. FIG. 11 illustrates three first gate electrodes GAT1 disposed on the second insulating layer IL2. One first gate electrode GAT_g among the three first gate electrodes GAT1 can be disposed such that the first gate electrode GAT_g overlaps with the first active layer ACT_g.

The third insulating layer IL3 can be disposed such that the third insulating layer IL3 covers the first gate electrodes GAT1.

A second gate electrode GAT2 can be disposed on the third insulating layer IL3.

The fourth insulating layer IL4 can be disposed such that the fourth insulating layer IL4 covers the third insulating layer IL3.

An active layer ACT_d of the driving transistor can be disposed on the fourth insulating layer IL4. The active layer ACT_d of the driving transistor can include one or more oxide particles. For example, the driving transistor can be an oxide TFT.

The gate electrode GAT_d of the driving transistor and the first interlayer insulating layer can be disposed on the active layer ACT_d of the driving transistor.

The fifth insulating layer IL5 can be disposed such that the fifth insulating layer IL5 covers the gate electrode GAT_d of the driving transistor.

Thereafter, contact holes can be formed in the fifth insulating layer IL5 and the fourth insulating layer IL4. First source-drain electrodes SD1 can be disposed through these contact holes.

The first planarization layer PLN1 can be disposed on the fifth insulating layer IL5. Additional contact holes can be formed in the first planarization layer PLN1, and second source-drain electrode SD2 can be disposed through these contact holes. The second source-drain electrode SD2 can be disposed in contact with the first source-drain electrode SD1.

The second planarization layer PLN2 can be disposed on the first planarization layer PLN1. A contact hole can be formed in the second planarization layer PLN2, and an anode layer can be disposed through this contact hole. The anode layer can be referred to as an anode electrode AE.

The light emitting element intermediate layer EL, the overhang structure OH, the encapsulation layer, and the like illustrated in FIG. 5 can be equally, or substantially equally, disposed on the anode electrode AE. For convenience of description, discussions on elements equal, or substantially equal, to these elements illustrated in FIG. 5 are omitted.

The components (GAT_d and ACT_d) of the driving transistor can be disposed in the display area. For example, the components (GAT_d and ACT_d) of the driving transistor can be disposed such that they overlap with the anode layer AE or the light emitting element intermediate layer EL. The components (GAT_g and ACT_g) of the transistor of the gate driving circuit can be disposed in the non-display area. In this implementation, the components (GAT_g and ACT_g) of the transistor of the gate driving circuit can be disposed in the second non-display area NDA2 shown in FIG. 3 or the fourth non-display area NDA4 shown in FIG. 3.

Referring to FIG. 12, in an embodiment, the components (GAT_d and ACT_d) of the driving transistor can be disposed in the non-display area. In this implementation, the components (GAT_d and ACT_d) of the driving transistors can be disposed in the second non-display area NDA2 shown in FIG. 3 or the fourth non-display area NDA4 shown in FIG. 3. In an embodiment, the components (GAT_g and ACT_g) of the transistor of the gate driving circuit can be disposed in the display area. For example, the components (GAT_d and ACT_d) of the transistor of the gate driving circuit can be disposed such that they overlap with the anode layer AE or the light emitting element intermediate layer EL.

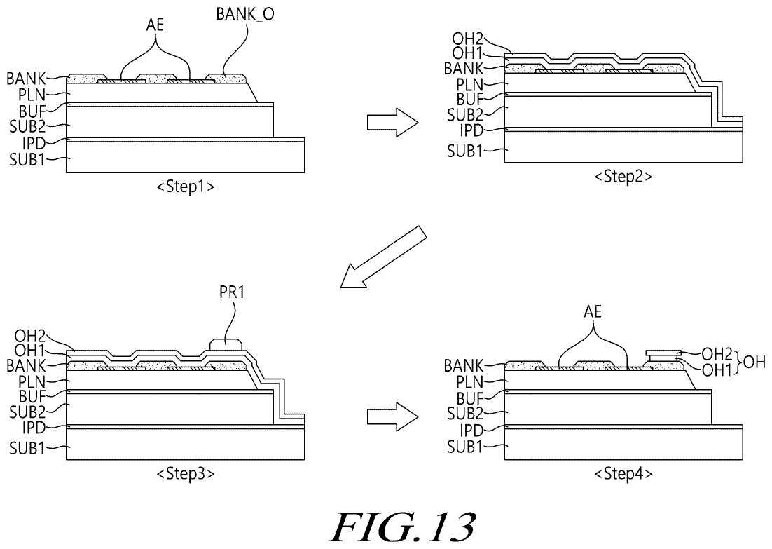

FIGS. 13, 14, and 15 illustrate an example manufacturing process of the display panel 110 according to aspects of the present disclosure.

Particularly, FIG. 13 illustrates first to fourth steps (Step 1, Step 2, Step 3, and Step 4) in the manufacturing process of the display panel 110. The first step (Step 1) of FIG. 13 illustrates a stack configuration in which an interlayer insulating layer IPD, a second substrate SUB2, an insulating layer IL, a planarization layer PLN, a bank BANK, and an anode layer AE are deposited on a first substrate SUB1. After the first step (Step 1), the process of forming an overhang structure OH on an outermost bank BANK_O can be performed.

Referring to the second step (Step 2) of FIG. 13, a first overhang structure OH1 can be deposited on a stack of the bank BANK and the anode layer AE so that the first overhang structure OH1 can cover the bank BANK and the anode layer AE. A second overhang structure OH2 can be deposited so that the second overhang structure OH2 can cover the first overhang structure OH1.

Referring to the third step (Step 3) of FIG. 13, a first photoresist PR1 can be deposited on the second overhang structure OH2 in an area overlapping with the outermost bank BANK_O. Thereafter, an etching process can be performed to form the overhang structure OH.

Referring to the fourth step (Step 4) of FIG. 13, the overhang structure OH can be disposed such that the overhang structure OH overlaps with the outermost bank BANK_O. The specific process of forming the overhang structure OH will be described in detail later. The overhang structure OH can include the first overhang structure OH1 and the second overhang structure OH2. A width of the second overhang structure OH2 (i.e., a distance between left and right ends of the second overhang structure OH2) can be greater than that of the first overhang structure OH1 (i.e., a distance between left and right ends of the first overhang structure OH1. A thickness of the first overhang structure OH1 can be greater than thickness of the second overhang structure OH2.

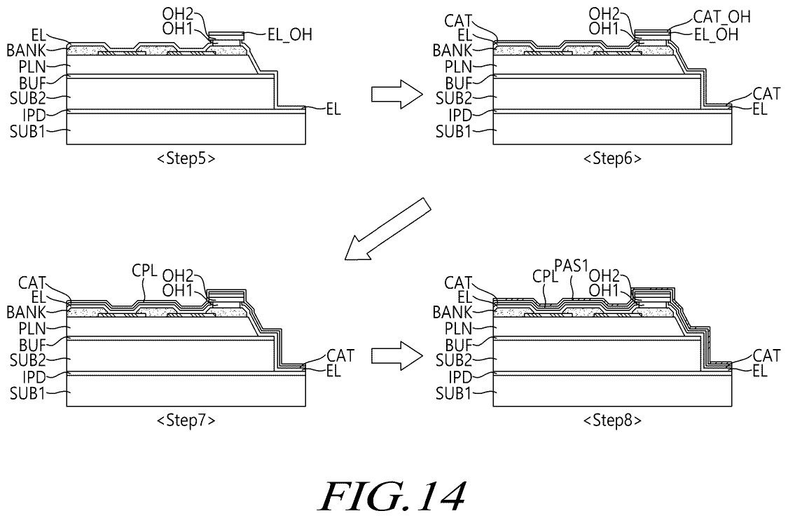

FIG. 14 illustrates fifth to eighth steps (Step 5, Step 6, Step 7, and Step 8) in the manufacturing process of the display panel 110.

Referring to the fifth step (Step 5) of FIG. 14, a light emitting element intermediate layer EL can be deposited on a stack of the bank BANK, the anode layer AE, and the overhang structure OH so that the light emitting element intermediate layer EL can cover the bank BANK, the anode layer AE, and the overhang structure OH. In this step, the light emitting element intermediate layer EL can be disposed in a form in which a portion of the light emitting element intermediate layer EL adjacent to the overhang structure OH is cut off. For example, the light emitting element intermediate layer EL can be deposited such that the portion of the light emitting element intermediate layer EL, which is disposed on the overhang structure OH and overlaps with the overhang structure OH, is cut off from portions of the light emitting element intermediate layer EL disposed on the sides of the overhang structure OH while being disposed on a stack of the bank BANK, the anode layer AE, and the overhang structure OH.

Referring to the sixth step (Step 6) of FIG. 14, a cathode layer CAT can be deposited on the light emitting element intermediate layer EL. In this step, the cathode layer CAT can be disposed in a form in which a portion of the cathode layer CAT adjacent to the overhang structure OH is cut off. For example, the cathode layer CAT can be deposited such that the portion of the cathode layer CAT, which is disposed on the overhang structure OH and overlaps with the overhang structure OH, is cut off from portions of the cathode layer CAT disposed on the sides of the overhang structure OH while being disposed on the light emitting element intermediate layer EL.

Referring to the seventh step (Step 7) of FIG. 14, a capping layer CPL can be deposited on the cathode layer CAT. The capping layer CPL can be deposited on the cathode layer CAT so that the capping layer CPL can cover the overhang structure OH.

Referring to the eighth step (Step 8) of FIG. 14, a first encapsulation layer PAS1 can be deposited such that the first encapsulation layer PAS1 covers the capping layer CPL.

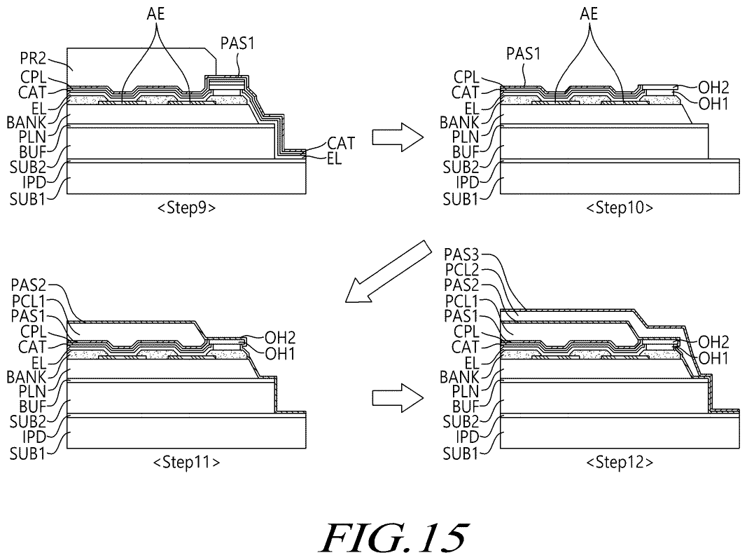

FIG. 15 illustrates ninth to twelfth steps (Step 9, Step 10, Step 11, and Step 12) in the manufacturing process of the display panel 110.

Referring to the ninth step (Step 9) of FIG. 15, a second photoresist PR2 can be deposited on the first encapsulation layer PAS1. The second photoresist PR2 can be disposed such that the second photoresist PR2 overlaps with a left portion of the overhang structure OH. The second photoresist PR2 can also be disposed in an area overlapping with the display area.

Referring to tenth step (Step 10) of FIG. 15, after the second photoresist PR2 is disposed, an etching process can be performed. As the etching process progresses, respective portions of the first encapsulation layer PAS1 disposed on the top and right side of the overhang structure OH can be etched and removed. As the etching process progresses, respective portions of the capping layer CPL disposed on the top and right side of the overhang structure OH can be etched and removed.

Referring to the eleventh step (Step 11) of FIG. 15, a second encapsulation layer PCL1 can be deposited on the first encapsulation layer PAS1. The second encapsulation layer PCL1 can be disposed in an area overlapping with the display area. A right edge of the second encapsulation layer PCL1 can overlap with a left edge of the overhang structure OH. A third encapsulation layer PAS2 can be deposited on the second encapsulation layer PCL1. The third encapsulation layer PAS2 can be deposited such that the third encapsulation layer PAS2 extends only up to a location covering the second encapsulation layer PCL1. The third encapsulation layer PAS2 can also be deposited such that the third encapsulation layer PAS2 covers the overhang structure OH. The first encapsulation layer PAS1 and the third encapsulation layer PAS2 can be inorganic encapsulation layers, and the second encapsulation layer PCL1 can be an organic encapsulation layer.

Referring to twelfth step (Step 12) of FIG. 15, a fourth encapsulation layer PCL2 can be deposited on the third encapsulation layer PAS2. The fourth encapsulation layer PCL2 can be deposited such that the fourth encapsulation layer PCL2 covers the overhang structure OH. A fifth encapsulation layer PAS3 can be deposited on the third encapsulation layer PAS2. The fourth encapsulation layer PCL2 can be an organic encapsulation layer, and the fifth encapsulation layer PAS3 can be an inorganic encapsulation layer.

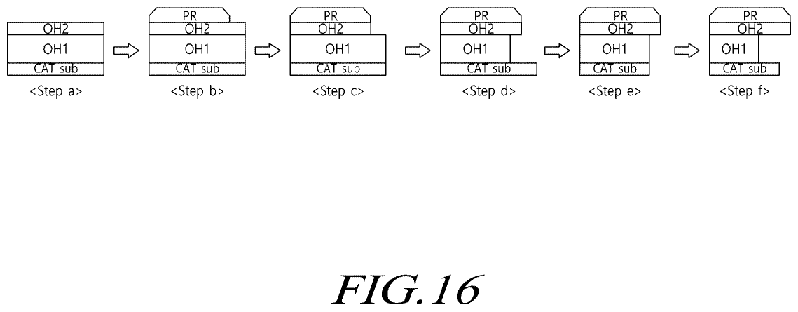

FIG. 16 illustrates an example process of forming an overhang structure OH in the display panel 110 according to aspects of the present disclosure.

Referring to FIG. 16, the process of forming one part of the overhang structure OH will be described. The process of forming a right portion (i.e., the outer portion) of the overhang structure OH shown in FIG. 5 will be described as an example.

Particularly, FIG. 16 illustrates first to sixth steps (Step a, Step b, Step c, Step d, Step e, and Step f).

Referring to the first step (Step a) of FIG. 16, a stack of an auxiliary cathode layer CAT_sub, a first overhang structure OH1, and a second overhang structure OH2 can be deposited. The auxiliary cathode layer CAT_sub can include metal such as molybdenum and titanium. The first overhang structure OH1 can include silicon oxide, or the like. The second overhang structure OH2 can include amorphous silicon, or the like.

Referring to the second step (Step b) of FIG. 16, a photoresist PR can be deposited on the second overhang structure OH2. A right edge of the photoresist PR can be shorter than that of the second overhang structure OH2.

Referring to the third step (Step c) of FIG. 16, after the photoresist PR is deposited, a first etching process can be performed. In the first etching process, amorphous silicon, or the like can be etched and removed. A right edge of the second overhang structure OH2 can be etched and removed. Due to this implementation, a right portion of the first overhang structure OH1 can protrude beyond a right end of the second overhang structure OH2.

Referring to the fourth step (Step d) of FIG. 16, thereafter, a second etching process can be performed. In the second etching process, silicon oxide, or the like can be etched and removed. A right edge of the first overhang structure OH1 can be etched and removed. Due to this implementation, a right portion of the second overhang structure OH2 can protrude beyond a right end of the first overhang structure OH1. A right portion of the auxiliary cathode layer CAT_sub can protrude beyond respective right ends of the first overhang structure OH1 and the second overhang structure OH2.

Referring to the fifth step (Step e) of FIG. 16, thereafter, a third etching process can be performed. In the third etching process, molybdenum, titanium, or the like can be etched and removed. A right edge of the auxiliary cathode layer CAT_sub can be etched and removed. A right end of the auxiliary cathode layer CAT_sub can align, or nearly align, with a right end of the first overhang structure OH1.

Referring to the sixth step (Step f) of FIG. 16, thereafter, a fourth etching process can proceed. In the fourth etching process, silicon oxide, or the like can be etched and removed. A right edge of the first overhang structure OH1 can be etched and removed. Due to this implementation, the right portion of the second overhang structure OH2 can further protrude beyond a right end of the first overhang structure OH1. Further, the right portion of the auxiliary cathode layer CAT_sub can protrude beyond the right edge of the first overhang structure OH1. For example, a width between left and right ends for each element can be “the second overhang structure OH2>the auxiliary cathode layer CAT_sub>the first overhang structure OH1. When the sixth step (Step f) shown in FIG. 16 is completed, the right portion of the overhang structure OH shown in FIG. 5 can be obtained. It should be appreciated that a left portion (i.e., the inner portion) of the overhanging structure OH shown in FIG. 5 can be formed by a similar process. As such, the overhang structure OH shown in FIG. 5 can be obtained.

A thickness of the first overhang structure OH1 can be greater than a sum of a thickness of the emission layer EL and a thickness of the cathode layer CAT. For example, the thickness of the first overhang structure OH1 can be equal to or greater than a sum of the thickness of the emission layer EL, the thickness of the cathode layer CAT, and a thickness of the capping layer CL.

The embodiments of the present disclosure described above will be briefly described as follows.

According to the embodiments of the present disclosure described herein, a display device can be provided that includes a substrate including a display area and a dam area, a planarization layer disposed over the substrate, an emission layer disposed on the planarization layer in the display area, an outermost bank on the planarization layer in the dam area, a first overhang structure disposed to overlap with the outermost bank, and a second overhang structure disposed to overlap with the first overhang structure.

The display device can further comprise a cathode layer disposed on the emission layer. The first overhang structure can contact the emission layer, and the second overhang structure can contact the cathode layer.

The second overhang structure can comprise metal, and the second overhang structure can be electrically connected to the cathode layer. The first overhang structure can comprise metal, and the first overhang structure can be electrically connected to the cathode layer.

The display device can further comprise an auxiliary cathode layer disposed between the first overhang structure and the outermost bank, and the auxiliary cathode layer can be electrically connected to the cathode layer. The first overhang structure can be spaced apart from the emission layer.

The display device can further comprise a capping layer disposed on the cathode layer, a first encapsulation layer disposed on the capping layer, a second encapsulation layer disposed on the first encapsulation layer, and a third encapsulation layer disposed on the second encapsulation layer.

The second encapsulation layer can cover the second overhang structure. The first overhang structure can contact the first encapsulation layer. The top surface of the second overhang structure can have a greater height than the top surface of the first encapsulation layer. The first encapsulation layer can be disposed between the emission layer and the first overhang structure.

The display device can further comprise a fourth encapsulation layer disposed on the third encapsulation layer and overlapping with the second overhang structure, and a fifth encapsulation layer disposed on the fourth encapsulation layer.

The display device can further comprise a transistor layer disposed on the substrate and including a driving transistor, and an anode layer electrically connected to a drain electrode or source electrode of the driving transistor. The first overhang structure can comprise silicon oxide, and the second overhang structure can comprise amorphous silicon.

According to the embodiments of the present disclosure described herein, a display device can be provided that includes a substrate comprising a display area and a dam area surrounding the display area, a planarization layer disposed on the substrate, an outermost bank disposed on the planarization layer in the dam area, a first overhang structure disposed on the outermost bank and overlapping with the outermost bank, a second overhang structure disposed on the first overhang structure and overlapping with the first overhang structure, and an emission layer disposed on the planarization layer and extending from the display area to the dam area and terminating at an inner side of the first overhang structure facing towards the display area.

The display device can further comprise a cathode layer disposed on the emission layer and extending from the display area to the dam area and terminating at the inner side of the first overhang structure, the cathode layer contacts the second overhang structure.

the second overhang structure comprises an electrically conductive material, and the second overhang structure is electrically connected to the cathode layer.

the second overhang structure comprises a first extension portion extending beyond the first overhang structure in a lateral inward direction towards the display area, the first extension portion comprises a bottom surface facing towards the substrate, and the cathode layer contacts the bottom surface of the first extension portion of the second overhang structure.

the emission layer contacts both the bottom surface of the first extension portion of the second overhang structure and the inner side of the first overhang structure, and the cathode layer is spaced apart from the inner side of the first overhang structure by the emission layer.

the cathode layer further contacts the inner side of the first overhang structure, and the first overhang structure comprises an electrically conductive material, and the first overhang structure is electrically connected to the cathode layer.

The display device can further comprise an auxiliary cathode layer disposed between the first overhang structure and the outermost bank, the cathode layer is electrically connected to the auxiliary cathode layer.

a width of the second overhang structure is greater than a width of the auxiliary cathode layer, and the width of the auxiliary cathode layer is greater than a width of the first overhang structure.

The display device can further comprise a cathode layer disposed on the emission layer and extending from the display area to the dam area and terminating at the inner side of the first overhang structure, the cathode layer contacts the inner side of the first overhang structure.

the first overhang structure comprises an electrically conductive material, and the first overhang structure is electrically connected to the cathode layer.

the emission layer is spaced apart from the first overhang structure by the cathode layer.

The display device can further comprise a cathode layer disposed on the emission layer and extending from the display area to the dam area and terminating at the inner side of the first overhang structure, a capping layer disposed on the cathode layer and extending from the display area to the dam area and terminating at the inner side of the first overhang structure, and a first encapsulation layer disposed on the capping layer.

the first encapsulation layer extends from the display area to the dam area and terminates at the inner side of the first overhang structure, and the first encapsulation layer contacts the inner side of the first overhang structure.

a top surface of the second overhang structure facing away from the substrate has a greater height than a top surface of the first encapsulation layer facing away from the substrate.

the second overhang structure comprises a first extension portion extending beyond the first overhang structure in a lateral inward direction towards the display area, the first extension portion comprises a bottom surface facing towards the substrate, and

the top surface of the first encapsulation layer contacts the bottom surface of the first extension portion of the second overhang structure.

the emission layer, the cathode layer and the capping layer are spaced apart from the first overhang structure and the second overhang structure by the first encapsulation layer.

The display device can further comprise a second encapsulation layer disposed on the first encapsulation layer and extending from the display area to the dam area, the second encapsulation layer terminates at and contacts with an inner side of the second overhang structure facing towards the display area.

The display device can further comprise a third encapsulation layer disposed on the second encapsulation layer and extending from the display area to the dam area, the third encapsulation layer covers a top surface of the second overhang structure facing away from the substrate, an outer side of the second overhang structure opposite to the inner side thereof, an outer side of the first overhang structure opposite to the inner side thereof, and an outer side of the outermost bank.

the first encapsulation layer extends from the display area to the dam area and terminates at an inner side of the second overhang structure facing towards the display area, and the first encapsulation layer contacts the inner side of the second overhang structure, and The display device can further comprise a second encapsulation layer disposed on the first encapsulation layer and extending from the display area to the dam area, the second encapsulation layer terminates at the inner side of the second overhang structure and is spaced apart from the inner side of the second overhang structure by the first encapsulation layer.

The display device can further comprise a third encapsulation layer disposed on the second encapsulation layer and extending from the display area to the dam area, the third encapsulation layer covers a top surface of the second overhang structure facing away from the substrate, an outer side of the second overhang structure opposite to the inner side thereof, an outer side of the first overhang structure opposite to the inner side thereof, and an outer side of the outermost bank.

the first encapsulation layer extends from the display area to the dam area and covers an inner side of the second overhang structure facing towards the display area, a top surface of the second overhang structure facing away from the substrate, an outer side of the second overhang structure opposite to the inner side thereof, an outer side of the first overhang structure opposite to the inner side thereof, and an outer side of the outermost bank.

the second overhang structure comprises a second extension portion extending beyond the first overhang structure in a lateral outward direction away from the display area, the second extension portion comprises a bottom surface facing towards the substrate, and the first encapsulation layer further covers the bottom surface of the second extension portion of the second overhang structure.

The display device can further comprise a second encapsulation layer disposed on the first encapsulation layer and extending from the display area to the dam area, the second encapsulation layer terminates at the inner side of the second overhang structure and is spaced apart from the inner side of the second overhang structure by the first encapsulation layer, and a third encapsulation layer covers the second encapsulation layer and the first encapsulation layer.

The display device can further comprise a fourth encapsulation layer disposed on the third encapsulation layer and overlapping with the second overhang structure, and a fifth encapsulation layer disposed on the fourth encapsulation layer.

the inner side of the first overhang structure is a first inner side, the first overhang structure further comprises a first outer side opposite to the first inner side, the first overhang structure has a first width between the first inner side and the first outer side, the second overhang structure comprises a second inner side facing towards the display area and a second outer side opposite to the second inner side, the second overhang structure has a second width between the second inner side and the second outer side, and the second width is greater than the first width.

the second overhang structure comprises a first extension portion extending beyond the first inner side of the first overhang structure in a lateral inward direction towards the display area, and the emission layer terminates at a position below the first extension portion of the second overhang structure.

the second overhang structure comprises a second extension portion extending beyond the first overhang structure in a lateral outward direction away from the display area.

The display device can further comprise a cathode layer disposed on the emission layer and extending from the display area to the dam area and terminating at the inner side of the first overhang structure, and a thickness of the first overhang structure is greater than a sum of a thickness of the emission layer and a thickness of the cathode layer.

The display device can further comprise a capping layer disposed on the cathode layer and extending from the display area to the dam area and terminating at the inner side of the first overhang structure, and the thickness of the first overhang structure equals to a sum of the thickness of the emission layer, the thickness of the cathode layer, and a thickness of the capping layer.

The display device can further comprise a transistor layer disposed on the substrate and including a driving transistor, an anode layer disposed on the planarization layer and electrically connected to a drain electrode or source electrode of the driving transistor, the emission layer is disposed on the anode layer, and a cathode layer disposed on the emission layer.

the first overhang structure comprises silicon oxide, and/or the second overhang structure comprises amorphous silicon.

The above description has been presented to enable any person skilled in the art to make, use and practice the technical features of the present invention, and has been provided in the context of a particular application and its requirements as examples. Various modifications, additions and substitutions to the described embodiments will be readily apparent to those skilled in the art, and the principles described herein can be applied to other embodiments and applications without departing from the scope of the present invention. The above description and the accompanying drawings provide examples of the technical features of the present invention for illustrative purposes only. For example, the disclosed embodiments are intended to illustrate the scope of the technical features of the present invention.

What is claimed is:

1. A display device comprising:
a substrate comprising a display area and a dam area adjacent to the display area;
a planarization layer disposed on the substrate;
an outermost bank disposed on the planarization layer in the dam area;
a first overhang structure disposed on the outermost bank and overlapping with the outermost bank;
a second overhang structure disposed on the first overhang structure and overlapping with the first overhang structure; and
an emission layer disposed on the planarization layer, and extending from the display area to the dam area and terminating at an inner side of the first overhang structure facing towards the display area.

2. The display device of claim 1, further comprising:
a cathode layer disposed on the emission layer, and extending from the display area to the dam area and terminating at the inner side of the first overhang structure,
wherein the cathode layer contacts the second overhang structure.

3. The display device of claim 2, wherein the second overhang structure comprises an electrically conductive material, and the second overhang structure is electrically connected to the cathode layer.

4. The display device of claim 2, wherein:
the second overhang structure comprises a first extension portion extending beyond the first overhang structure in a lateral inward direction towards the display area,
the first extension portion comprises a bottom surface facing towards the substrate, and
the cathode layer contacts the bottom surface of the first extension portion of the second overhang structure.

5. The display device of claim 4, wherein:
the emission layer contacts both the bottom surface of the first extension portion of the second overhang structure and the inner side of the first overhang structure, and
the cathode layer is spaced apart from the inner side of the first overhang structure by the emission layer.

6. The display device of claim 2, wherein:
the cathode layer further contacts the inner side of the first overhang structure, and
the first overhang structure comprises an electrically conductive material, and the first overhang structure is electrically connected to the cathode layer.

7. The display device of claim 2, further comprising:
an auxiliary cathode layer disposed between the first overhang structure and the outermost bank,
wherein the cathode layer is electrically connected to the auxiliary cathode layer.

8. The display device of claim 7, wherein a width of the second overhang structure is greater than a width of the auxiliary cathode layer, and the width of the auxiliary cathode layer is greater than a width of the first overhang structure.

9. The display device of claim 1, further comprising:
a cathode layer disposed on the emission layer, and extending from the display area to the dam area and terminating at the inner side of the first overhang structure,
wherein the cathode layer contacts the inner side of the first overhang structure.

10. The display device of claim 9, wherein the first overhang structure comprises an electrically conductive material, and the first overhang structure is electrically connected to the cathode layer.

11. The display device of claim 2, wherein the emission layer is spaced apart from the first overhang structure by the cathode layer.

12. The display device of claim 1, further comprising:
a cathode layer disposed on the emission layer, and extending from the display area to the dam area and terminating at the inner side of the first overhang structure;
a capping layer disposed on the cathode layer, and extending from the display area to the dam area and terminating at the inner side of the first overhang structure; and
a first encapsulation layer disposed on the capping layer.

13. The display device of claim 12, wherein the first encapsulation layer extends from the display area to the dam area and terminates at the inner side of the first overhang structure, and the first encapsulation layer contacts the inner side of the first overhang structure.

14. The display device of claim 13, wherein a top surface of the second overhang structure facing away from the substrate has a greater height than a top surface of the first encapsulation layer facing away from the substrate.

15. The display device of claim 14, wherein:
the second overhang structure comprises a first extension portion extending beyond the first overhang structure in a lateral inward direction towards the display area,
the first extension portion comprises a bottom surface facing towards the substrate, and
the top surface of the first encapsulation layer contacts the bottom surface of the first extension portion of the second overhang structure.

16. The display device of claim 13, wherein the emission layer, the cathode layer and the capping layer are spaced apart from the first overhang structure and the second overhang structure by the first encapsulation layer.

17. The display device of claim 13, further comprising:
a second encapsulation layer disposed on the first encapsulation layer and extending from the display area to the dam area,
wherein the second encapsulation layer terminates at and contacts with an inner side of the second overhang structure facing towards the display area.

18. The display device of claim 17, further comprising:
a third encapsulation layer disposed on the second encapsulation layer and extending from the display area to the dam area,
wherein the third encapsulation layer covers a top surface of the second overhang structure facing away from the substrate, an outer side of the second overhang structure opposite to the inner side thereof, an outer side of the first overhang structure opposite to the inner side thereof, and an outer side of the outermost bank.

19. The display device of claim 12, wherein:
the first encapsulation layer extends from the display area to the dam area and terminates at an inner side of the second overhang structure facing towards the display area,
the first encapsulation layer contacts the inner side of the second overhang structure,
the display device further comprises a second encapsulation layer disposed on the first encapsulation layer and extending from the display area to the dam area, and
the second encapsulation layer terminates at the inner side of the second overhang structure and is spaced apart from the inner side of the second overhang structure by the first encapsulation layer.

20. The display device of claim 19, further comprising:
a third encapsulation layer disposed on the second encapsulation layer and extending from the display area to the dam area,
wherein the third encapsulation layer covers a top surface of the second overhang structure facing away from the substrate, an outer side of the second overhang structure opposite to the inner side thereof, an outer side of the first overhang structure opposite to the inner side thereof, and an outer side of the outermost bank.

21. The display device of claim 12, wherein the first encapsulation layer extends from the display area to the dam area and covers an inner side of the second overhang structure facing towards the display area, a top surface of the second overhang structure facing away from the substrate, an outer side of the second overhang structure opposite to the inner side thereof, an outer side of the first overhang structure opposite to the inner side thereof, and an outer side of the outermost bank.

22. The display device of claim 21, wherein:
the second overhang structure comprises a second extension portion extending beyond the first overhang structure in a lateral outward direction away from the display area,
the second extension portion comprises a bottom surface facing towards the substrate, and
the first encapsulation layer further covers the bottom surface of the second extension portion of the second overhang structure.

23. The display device of claim 21, further comprising:
a second encapsulation layer disposed on the first encapsulation layer and extending from the display area to the dam area, wherein the second encapsulation layer terminates at the inner side of the second overhang structure and is spaced apart from the inner side of the second overhang structure by the first encapsulation layer; and
a third encapsulation layer covering the second encapsulation layer and the first encapsulation layer.

24. The display device of claim 18, further comprising:
a fourth encapsulation layer disposed on the third encapsulation layer and overlapping with the second overhang structure; and
a fifth encapsulation layer disposed on the fourth encapsulation layer.

25. The display device of claim 1, wherein:
the inner side of the first overhang structure is a first inner side,
the first overhang structure further comprises a first outer side opposite to the first inner side,
the first overhang structure has a first width between the first inner side and the first outer side,
the second overhang structure comprises a second inner side facing towards the display area and a second outer side opposite to the second inner side,
the second overhang structure has a second width between the second inner side and the second outer side, and
the second width is greater than the first width.

26. The display device of claim 25, wherein:
the second overhang structure comprises a first extension portion extending beyond the first inner side of the first overhang structure in a lateral inward direction towards the display area, and
the emission layer terminates at a position below the first extension portion of the second overhang structure.

27. The display device of claim 25, wherein:
the second overhang structure comprises a second extension portion extending beyond the first overhang structure in a lateral outward direction away from the display area.

28. The display device of claim 1, wherein:
the display device further comprises a cathode layer disposed on the emission layer and extending from the display area to the dam area and terminating at the inner side of the first overhang structure, and
a thickness of the first overhang structure is greater than a sum of a thickness of the emission layer and a thickness of the cathode layer.

29. The display device of claim 28, wherein:
the display device further comprises a capping layer disposed on the cathode layer and extending from the display area to the dam area and terminating at the inner side of the first overhang structure, and
the thickness of the first overhang structure equals to a sum of the thickness of the emission layer, the thickness of the cathode layer, and a thickness of the capping layer.

30. The display device of claim 1, further comprising:
a transistor layer disposed on the substrate and including a driving transistor;
an anode layer disposed on the planarization layer and electrically connected to a drain electrode or source electrode of the driving transistor, wherein the emission layer is disposed on the anode layer; and
a cathode layer disposed on the emission layer.

31. The display device of claim 1, wherein the first overhang structure comprises silicon oxide, or the second overhang structure comprises amorphous silicon.
